(19) United States
(12) Patent Application Publication
(10) Pub. No.: US 2023/0275569 A1
(43) Pub. Date: Aug. 31, 2023

(54) ELASTIC WAVE RESONATOR, ELASTIC WAVE FILTER, DEMULTIPLEXER, AND COMMUNICATION APPARATUS

(71) Applicant: KYOCERA CORPORATION, Kyoto-shi, Kyoto (JP)

(72) Inventors: Soichiro NOZOE, Soraku-gun (JP); Tetsuya KISHINO, Nara-shi (JP)

(73) Assignee: KYOCERA CORPORATION, Kyoto-shi, Kyoto (JP)

(21) Appl. No.: 18/017,898

(22) PCT Filed: Jul. 29, 2021
(86) PCT No.: PCT/JP2021/028001

§ 371 Date: Jan. 25, 2023

(30) Foreign Application Priority Data
Jul. 30, 2020 (JP) 2020-129432

(51) Int. Cl. H03H 9/25; H03H 9/64

(52) U.S. Cl. CPC H03H 9/25; H03H 9/6483

(57) ABSTRACT

An elastic wave resonator includes a piezoelectric body, an IDT electrode positioned on the piezoelectric body, and a pair of reflectors. The IDT electrode includes a plurality of first electrode fingers arranged at a first pitch in a propagation direction of an elastic wave, and at least one second electrode finger formed at each end in the propagation direction of the plurality of first electrode fingers. The reflector is positioned at each end in the propagation direction of the IDT electrode and includes a plurality of strip electrodes arranged, in the propagation direction, at a second pitch wider than the first pitch or having a duty ratio higher than a duty ratio of any of the plurality of first electrode fingers and the at least one second electrode finger.

### TECHNICAL FIELD

The present disclosure relates to an elastic wave resonator.

### BACKGROUND OF INVENTION

Known Literature 1 describes an elastic wave filter including a plurality of interdigital transducers having a certain specific resonant frequency on a piezoelectric substrate.

### CITATION LIST

### Patent Literature

Patent Document 1: WO 2005/050837

### SUMMARY

An elastic wave resonator according to one aspect of the present disclosure is an elastic wave resonator that excites a plate wave excited in an A1 mode in a piezoelectric body, the elastic wave resonator includes: the piezoelectric body; an IDT electrode positioned on the piezoelectric body and including a plurality of first electrode fingers arranged at a first pitch in a propagation direction of an elastic wave, and at least one second electrode finger formed at each end in the propagation direction of the first electrode fingers; and a pair of reflectors including a plurality of strip electrodes arranged, in the propagation direction, at a second pitch wider than the first pitch, or a plurality of strip electrodes having a duty ratio higher than a duty ratio of the plurality of first electrode fingers or the at least one second electrode finger, the pair of reflectors being positioned at each end in the propagation direction of the IDT electrode on the piezoelectric body.

An elastic wave resonator according to another aspect of the present disclosure includes: a piezoelectric body; an IDT electrode positioned on the piezoelectric body and including a plurality of first electrode fingers arranged, in a propagation direction of an elastic wave, at a first pitch larger than ½ times a thickness of the piezoelectric body, and at least one second electrode finger formed at each end in the propagation direction of the first electrode fingers; and a pair of reflectors including a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being positioned at each end in the propagation direction of the IDT electrode on the piezoelectric body.

An elastic wave resonator according to another aspect of the present disclosure includes: a support substrate; a reflective multilayer film positioned on the support substrate; a piezoelectric body positioned on an opposite side of the reflective multilayer film from the support substrate; an IDT electrode positioned on the piezoelectric body on an opposite side from the support substrate and including a plurality of first electrode fingers arranged at a first pitch in a propagation direction of an elastic wave, and at least one second electrode finger formed at each of ends in the propagation direction of the first electrode fingers; and a pair of reflectors including a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being positioned at each end in the propagation direction of the IDT electrode on the piezoelectric body.

An elastic wave resonator according to another aspect of the present disclosure includes: a piezoelectric body; a support substrate supporting the piezoelectric body, including a recessed portion at a position overlapping a part of the piezoelectric body in plan view, and including a gap between the support substrate and the piezoelectric body at a position overlapping the recessed portion in plan view; an IDT electrode positioned on the piezoelectric body on an opposite side from the support substrate, and including a plurality of first electrode fingers arranged at a first pitch in a propagation direction of an elastic wave, and at least one second electrode finger formed at each of both ends in the propagation direction of the first electrode fingers; and a pair of reflectors including a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being positioned at each end in the propagation direction of the IDT electrode on the piezoelectric body.

### BRIEF DESCRIPTION OF THE DRAWINGS

FIG. 1 is a schematic plan view of an elastic wave resonator according to a first embodiment of the present disclosure.

FIG. 2 is a schematic cross-sectional view of the elastic wave resonator according to the first embodiment of the present disclosure.

FIG. 3 is a graph showing a relationship among a ratio of a first pitch to a second pitch, a maximum phase, and a spurious index for an elastic wave resonator according to Example 1.

FIG. 4 is a graph showing a relationship among a ratio of a first pitch to a gap, a spurious index, and the number of second electrode fingers for the elastic wave resonator according to Example 1.

FIG. 5 is a graph showing a relationship among a ratio of a first pitch to a gap, a maximum phase, and the number of second electrode fingers for the elastic wave resonator according to Example 1.

FIG. 6 is a graph comparing characteristics of the elastic wave resonator according to Example 1 and an elastic wave resonator according to Comparative Examples 1 and 2.

FIG. 7 is a graph showing a relationship among a ratio of a first pitch to a second pitch, a maximum phase, and a spurious index for an elastic wave resonator according to Example 2.

FIG. 8 is a graph showing a relationship among a ratio of a first pitch to a gap, a spurious index, and the number of second electrode fingers for the elastic wave resonator according to Example 2.

FIG. 9 is a graph showing a relationship among a ratio of a first pitch to a gap, a maximum phase, and the number of second electrode fingers for the elastic wave resonator according to Example 2.

FIG. 10 is a graph comparing characteristics of the elastic wave resonator according to Example 2 and an elastic wave resonator according to Comparative Example 3.

FIG. 11 is a graph showing a relationship among a ratio of a first pitch to a gap, a spurious index, and the number of second electrode fingers for the elastic wave resonator according to Example 3.

FIG. 12 is a graph comparing characteristics of the elastic wave resonator according to Example 3 and an elastic wave resonator according to Comparative Example 4.

FIG. 13 is a graph showing a relationship among a ratio of a first pitch to a second pitch, a maximum phase, and a spurious index regarding the elastic wave resonator according to Example 4.

FIG. 14 is a graph showing a relationship among a ratio of a first pitch to a gap, a spurious index, and the number of second electrode fingers for the elastic wave resonator according to Example 4.

FIG. 15 is a graph showing a relationship among a ratio of a first pitch to a gap, a maximum phase, and the number of second electrode fingers for the elastic wave resonator according to Example 4.

FIG. 16 is a graph comparing characteristics of the elastic wave resonator according to Example 4 and an elastic wave resonator according to Comparative Example 5.

FIG. 17 is a graph showing a relationship between a duty ratio of a strip electrode and the maximum phase for the elastic wave resonator according to Example 5.

FIG. 18 is a graph showing a relationship among a ratio of a first pitch to a gap, a spurious index, and a duty ratio of the strip electrode for the elastic wave resonator according to Example 5.

FIG. 19 is a schematic cross-sectional view of an elastic wave resonator according to a second embodiment of the present disclosure.

FIG. 20 is a schematic view illustrating a communication apparatus according to each embodiment of the present disclosure.

FIG. 21 is a circuit diagram illustrating a demultiplexer according to each embodiment of the present disclosure.

### DESCRIPTION OF EMBODIMENTS

### First Embodiment

Embodiments according to the present disclosure will be described below with reference to the drawings. The drawings used in the following description are schematic views, and do not strictly indicate dimensional ratios of members on the drawings.

Overall Configuration of Resonator

An elastic wave filter according to the present embodiment includes at least one elastic wave resonator. For example, the elastic wave filter constitutes a ladder filter by connecting a plurality of elastic wave resonators in a ladder form. The elastic wave filter according to the present embodiment may include the plurality of elastic wave resonators in parallel in a direction orthogonal to a propagation direction of elastic waves in each of the elastic wave resonators.

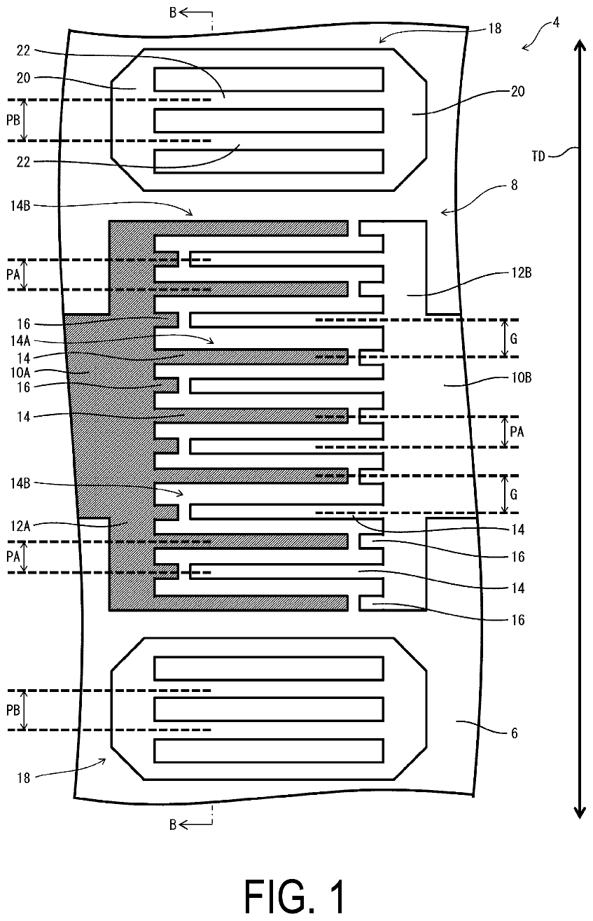

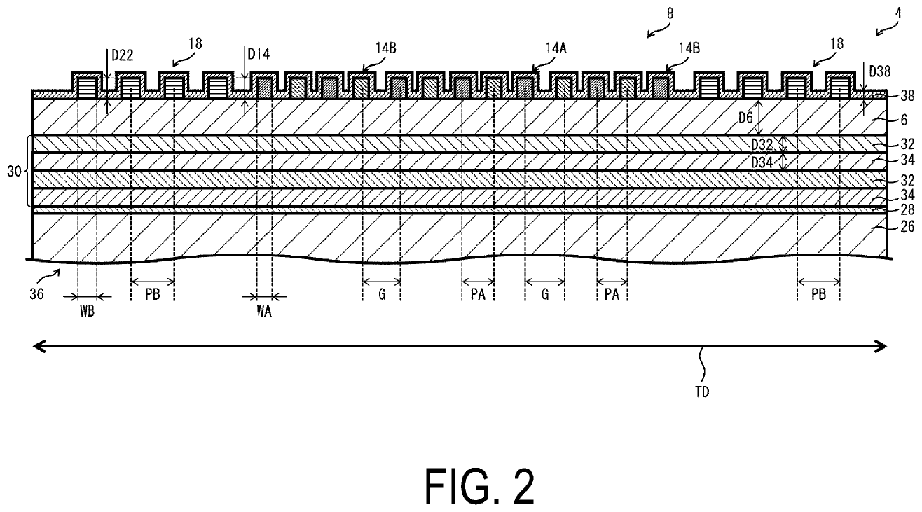

Hereinafter, an elastic wave resonator 4 according to the present embodiment will be described in more detail with reference to FIGS. 1 and 2. FIG. 1 is a schematic plan view of an elastic wave resonator 4 according to the present embodiment, and is an enlarged plan view of a region A in FIG. 2. FIG. 2 is a schematic cross-sectional view of the elastic wave resonator 4 according to the present embodiment, and is a cross-sectional view taken along arrow line B-B in FIG. 1.

In the present description, a propagation direction TD of an elastic wave in the elastic wave resonator 4 is defined as the up-down direction in a plan view, such as FIG. 1, of the elastic wave resonator 4, and defined as the left-right direction in a cross-sectional view, such as FIG. 2, of the elastic wave resonator 4. In the present description, in the cross-sectional view, such as FIG. 2, of the elastic wave resonator 4, only the members in the cross section are illustrated, and the members behind the members in the cross section are omitted for the sake of simplicity of the drawings. In FIG. 1, a protective film 38 illustrated in FIG. 2 and described later in detail is not illustrated.

Piezoelectric Body and IDT Electrode

As illustrated in FIGS. 1 and 2, the elastic wave resonator 4 according to the present embodiment at least includes a piezoelectric body 6 and an IDT electrode 8 on the piezoelectric body 6. In the cross-sectional view, such as FIG. 2, of the elastic wave resonator 4 of the present description, the IDT electrode 8 is positioned on the upper side of the piezoelectric body 6 in plan view.

The piezoelectric body 6 is made of a piezoelectric material, and for example, lithium niobate or a single crystal of lithium tantalate (hereinafter, also referred to as LT) may be used. When a voltage is applied to an electrically conductive layer including the IDT electrode 8 described later in the elastic wave resonator 4, an elastic wave propagating through the piezoelectric body 6 in the propagation direction TD is excited. In the present embodiment, the piezoelectric body 6 may have a constant thickness D6 as illustrated in FIG. 2. In the present description, the term “thickness is constant” does not necessarily mean that the thickness is strictly constant, and some variation is allowed within a range that does not significantly affect the characteristics of the elastic wave propagating through the piezoelectric body 6.

The IDT electrode 8 includes a pair of comb electrodes 10. In particular, in the present embodiment, as illustrated in FIG. 1, the comb electrode 10 includes a first comb electrode 10A and a second comb electrode 10B as a pair of comb electrodes. In the present description, in plan view of the elastic wave resonator 4, such as FIG. 1, the first comb electrode 10A is hatched to improve visibility. Each of the comb electrodes 10 includes, for example, a bus bar 12, a plurality of electrode fingers 14 each extending from the bus bar 12, and a plurality of dummy electrodes 16 projecting from the bus bar 12 between the electrode fingers 14. The pair of comb electrodes 10 are arranged in such a manner that the plurality of electrode fingers 14 intermesh with each other. In the present description, when simply described as “electrode finger”, the “electrode finger” includes a plurality of electrode fingers 14 of the IDT electrode 8.

The bus bar 12 has a substantially constant width and is formed substantially along the propagation direction TD. The pair of bus bars 12 face each other in a direction substantially orthogonal to the propagation direction TD. In particular, the bus bar 12 includes a first bus bar 12A formed as a bus bar of the first comb electrode 10A, and a second bus bar 12B facing the first bus bar 12A and formed as a bus bar of the second comb electrode 10B. To the extent that the elastic wave propagating through the piezoelectric body 6 is not significantly affected, the bus bar 12 may vary in width or may be formed inclined from the propagation direction TD.

Each of the electrode fingers 14 is formed in an elongated shape substantially along the width direction of the bus bar 12. In each of the comb electrodes 10, each of the electrode fingers 14 is arranged in the propagation direction TD. The electrode fingers 14 extending from one of the paired bus bars 12 and the electrode fingers 14 extending from the other one of the paired bus bars 12 are alternately arranged in the propagation direction TD.

The number of electrode fingers 14 is not limited to the number illustrated in FIG. 1, and may be appropriately determined in accordance with the characteristics required for the elastic wave resonator 4. The lengths of the electrode fingers 14 may be substantially constant as illustrated in FIG. 1, or the lengths may be so-called apodized, where the lengths differ from each other in accordance with the position in the propagation direction TD. In a part of the IDT electrode 8, some of the electrode fingers 14 may be “thinned out”. In other words, the IDT electrode 8 may partially include a region where some of the electrode fingers 14 are not formed.

Each dummy electrode 16 projects substantially along the width direction of the bus bar 12. The dummy electrodes 16 projecting from one bus bar 12 face the tips of the electrode fingers 14 extending from the other bus bar 12 via a gap in a direction orthogonal to the propagation direction TD. The elastic wave resonator 4 according to the present embodiment needs not include the dummy electrodes 16.

Pitch and Gap of Electrode Finger

In the present embodiment, the IDT electrode 8 includes a first electrode finger 14A and a second electrode finger 14B as the electrode fingers 14. A plurality of first electrode fingers 14A are arranged at a first pitch PA in the propagation direction TD. At least one second electrode finger 14B is formed at each of ends in the propagation direction TD of the plurality of first electrode fingers 14A. Thus, the first electrode finger 14A is formed between the second electrode fingers 14B in the propagation direction TD.

The second electrode finger 14B is formed at each of ends in the propagation direction TD of the plurality of first electrode fingers 14A with a gap G wider than the first pitch PA. In other words, in the propagation direction TD, a gap G is formed between an end on the first electrode finger 14A side of the second electrode finger 14B formed on one side of the two ends of the first electrode finger 14A and an end on the one side of the first electrode finger 14A.

A plurality of second electrode fingers 14B may be formed at each of the ends in the propagation direction TD of the first electrode finger 14A. In this case, the plurality of second electrode fingers 14B may be arranged at the first pitch PA in the propagation direction TD. The same number of second electrode fingers 14B may be formed at each of ends in the propagation direction TD of the first electrode finger 14A. With this configuration, since the first electrode fingers 14A and the second electrode fingers 14B are formed symmetrically in the propagation direction TD to improve the characteristics of the elastic wave excited by the elastic wave resonator 4.

In the present embodiment, some of the first electrode fingers 14A and some of the second electrode fingers 14B may extend from the first bus bar 12A. In this case, the others of the first electrode fingers 14A and the others of the second electrode fingers 14B may extend from the second bus bar 12B. The first electrode fingers 14A and the second electrode fingers 14B extending from the first bus bar 12A and the first electrode fingers 14A and the second electrode fingers 14B extending from the second bus bar 12B may be alternately arranged in the propagation direction TD.

Thus, the first electrode fingers 14A and the second electrode fingers 14B extending from the first bus bar 12A may face the respective dummy electrodes 16 extending from the second bus bars 12B via a void. The first electrode fingers 14A and the second electrode fingers 14B extending from the second bus bar 12B may face the respective dummy electrodes 16 extending from the first bus bar 12A via a void.

Both the first electrode finger 14A and the second electrode finger 14B may have a width WA in the propagation direction TD. The duty ratio of the first electrode finger 14A and the second electrode finger 14B can be designed by appropriately designing the first pitch PA and the width WA for the first electrode finger 14A and the second electrode finger 14B. In general, the duty ratio of an electrode finger is a value obtained by dividing the width of the electrode finger in the propagation direction of the elastic wave by the pitch between the electrode finger and the adjacent electrode finger. In the present embodiment, the duty ratio of the first electrode finger 14A and the second electrode finger 14B is, for example, 0.55. Both the first electrode finger 14A and the second electrode finger 14B may have a thickness D14 in a direction perpendicular to the in-plane direction of the elastic wave resonator 4.

Here, the resonant frequency of the elastic waves propagating through the piezoelectric body 6 and excited by the elastic wave resonator 4 depends on the pitch and the duty ratio of the electrode finger 14. In general, the resonant frequency of the elastic wave excited by the elastic wave resonator 4 increases as the pitch of the electrode fingers 14 decreases or the duty ratio of the electrode fingers 14 decreases.

In the present description, the term “resonant frequency” refers to a resonant frequency of an elastic wave excited by the elastic wave resonator 4 in a main resonance mode, and does not refer to a frequency of an elastic wave excited in a sub-resonance mode or a spurious mode.

In the present embodiment, the first pitch PA is, for example, about 1.0 μm. The first pitch PA is larger than ½ times the thickness D6 of the piezoelectric body 6. In other words, the thickness D6 of the piezoelectric body 6 is less than twice the first pitch PA. In the elastic wave resonator 4 according to the present embodiment, a plate wave of an A1 mode elastic wave excited in a main resonance mode is used among the excited elastic waves.

When the piezoelectric body 6 contains lithium tantalate, the cut angle of the piezoelectric body 6 may be appropriately determined in a range of (0°±20°, −5° or greater and 65° or less, 0°±10°). When the piezoelectric body 6 contains lithium niobate, the cut angle of the piezoelectric body 6 may be appropriately determined in a range of (0°, 0°±20°, 0° or greater and 360° or less).

The gap G may be wider than the first pitch PA. Alternatively, the gap G may be equal to or less than twice the first pitch PA. Such configuration makes it possible to reduce the polarity inversion between the electrode fingers 14 adjacent to each other via the gap Gin the propagation direction TD.

Reflector The elastic wave resonator 4 further includes a pair of reflectors 18 each located at respective ends of the electrode fingers 14 in the propagation direction TD on the piezoelectric body 6. The reflector 18 includes a plurality of strip electrodes 22 extending from a pair of bus bars 20 facing each other. The reflector 18 may be in an electrically floating state, or a reference potential may be applied to the reflector 18. The IDT electrode 8 and the reflector 18 may be the same layer or may be included in the electrically conductive layer. The IDT electrode 8 and the reflector 18 may be made of a metal material, and may be made of, for example, an AL-based alloy. The number, shape, and the like of each of the strip electrodes 22 of the reflector 18 are not limited to the configuration illustrated in FIG. 1, and may be appropriately designed in accordance with the characteristics required for the elastic wave resonator 4 as in the case of the electrode fingers 14.

In the present embodiment, the plurality of strip electrodes 22 is arranged at a second pitch PB in the propagation direction TD. The strip electrode 22 may have a width WB in the propagation direction TD. The strip electrode 22 may have a thickness D22 in a direction perpendicular to the in-plane direction of the elastic wave resonator 4. Here, the duty ratio of the strip electrode 22 can be designed by appropriately designing the second pitch PB and the width WB of the strip electrode 22.

The duty ratio of the strip electrode 22 can be obtained by the same method as the method for obtaining the duty ratio of the electrode finger 14. Specifically, the duty ratio of the specific strip electrode 22 is obtained by dividing the width WB of the strip electrode 22 by the pitch between the strip electrode 22 and the adjacent strip electrode 22.

Here, in the present embodiment, the second pitch PB is larger than the first pitch PA, or the duty ratio of the strip electrode 22 is higher than the duty ratio of either the first electrode finger 14A or the second electrode finger 14B.

Function and Design of Reflector The reflector 18 has a function of exciting at a position overlapping the IDT electrode 8 in plan view and reflecting an elastic wave propagating on the reflector 18 side in the propagation direction TD to the IDT electrode 8 side in the propagation direction TD. The frequency of the elastic wave reflected by the reflector 18 depends on the pitch and the duty ratio of the strip electrode 22 of the reflector 18. In general, an increase in the pitch of the strip electrode 22 or an increase in the duty ratio means a decrease in the frequency of the elastic wave reflected by the reflector 18.

In general, in the elastic wave excited at the position overlapping the IDT electrode 8 in plan view, an elastic wave excited in a mode different from main resonance and anti-main resonance may be generated, in addition to the elastic wave excited in the main resonance or anti-main resonance mode. The elastic wave is an elastic wave that is excited in a mode generally called a spurious mode, and can be a factor of deteriorating characteristics of the elastic wave resonator 4. Thus, in the elastic wave resonator 4, the elastic wave reflected by the reflector 18 may not include the elastic wave excited in the spurious mode.

By lowering the frequency of the elastic wave reflected by the reflector 18, reflection at the reflector 18 of the elastic wave excited in the high-frequency spurious mode can be reduced. Thus, the elastic wave resonator 4 according to the present embodiment including the reflector 18 having a low frequency of the reflected elastic wave can reduce the intensity of the elastic wave excited in the high-frequency spurious mode.

On the other hand, as the frequency of the elastic wave reflected by the reflector 18 is lowered, the elastic wave excited in the low-frequency spurious mode is reflected by the reflector 18. Thus, the elastic wave resonator 4 according to the present embodiment including the reflector 18 having a low frequency of the reflected elastic wave may further include a mechanism for reducing the intensity of the elastic wave excited in the low-frequency spurious mode.

Relationship between Gap and Improvement in Characteristics Here, a known elastic wave resonator in which the main resonance mode is different from the A1 mode unlike the elastic wave resonator 4 according to the present embodiment will be described. In the known elastic wave resonator, it is generally known that an elastic wave excited in a low-frequency spurious mode is reduced by bringing a reflector close to an IDT electrode in a propagation direction of the elastic wave. This corresponds to reducing the gap G in the elastic wave resonator 4 according to the present embodiment.

From the above, in the above-described known elastic wave resonator, the reflector may be brought close to the IDT electrode in the propagation direction of the elastic wave while lowering the frequency of the elastic wave reflected by the reflector. As a result, the elastic wave excited in the spurious mode is reduced on both the low-frequency side and the high-frequency side. This corresponds to reducing the gap G while widening the second pitch PB or increasing the duty ratio of the strip electrode 22 in the elastic wave resonator 4 according to the present embodiment.

On the other hand, when the main resonance mode of a plate wave is the A1 mode, as in the elastic wave resonator 4 according to the present embodiment, a new finding different from the above has been found. Specifically, it has been found that, in the elastic wave resonator 4, the elastic wave excited in the spurious mode is reduced by increasing the gap G while widening the second pitch PB of the strip electrode 22 of the reflector 18 or increasing the duty ratio.

A newly found design of the elastic wave resonator 4 according to the present embodiment is a design opposite to the design of a known elastic wave resonator in which the main resonance mode is different from the A1 mode. Thus, the above-described new finding is not easily found from the known elastic wave resonator.

Fixation Substrate Returning to the description of each configuration of the elastic wave resonator 4, as illustrated in FIG. 2, the elastic wave resonator 4 further includes a support substrate 26 on the side opposite from the IDT electrode 8 relative to the piezoelectric body 6. In the present embodiment, the effect of the support substrate 26 on the characteristics of the elastic wave propagating through the piezoelectric body 6 is sufficiently small. Thus, the material and dimensions of the support substrate 26 may be appropriately designed. For example, the support substrate 26 may contain an insulation material, and may contain a resin or a ceramic. The thickness of the support substrate 26 is, for example, greater than the thickness D6 of the piezoelectric body 6. In order to further reduce the influence on the characteristics of the elastic wave with a temperature change, the support substrate 26 may be made of a material having a linear expansion coefficient lower than the linear expansion coefficient of the piezoelectric body 6.

In addition, the elastic wave resonator 4 includes a reflective multilayer film 30 between the piezoelectric body 6 and the support substrate 26. The elastic wave resonator 4 may include a cohesion layer 28 between the reflective multilayer film 30 and the support substrate 26. A laminate body including the piezoelectric body 6, the support substrate 26, the cohesion layer 28, and the reflective multilayer film 30 may be referred to as fixation substrate 36.

The cohesion layer 28 is a layer inserted in order to improve adhesiveness between the support substrate 26 and the reflective multilayer film 30, and the effect by the cohesion layer 28 on the characteristics of the elastic wave propagating through the piezoelectric body 6 is sufficiently small.

The reflective multilayer film 30 includes first layers 32 and second layers 34, and these layers are alternately layered. The material of the first layer 32 has low acoustic impedance compared with the material of the second layer 34. As a result, the reflectance of the elastic wave is increased at an interface between the first layer 32 and the second layer 34, thereby reducing the leakage of the elastic wave propagating through the piezoelectric body 6 to the outside of the elastic wave filter.

For example, the first layer 32 contains silicon dioxide (SiO₂) as a main ingredient. For example, the second layer 34 contains hafnium oxide (HfO₂) as a main ingredient. In addition, the second layer 34 may contain any of tantalum pentoxide (Ta₂O₅), zirconium dioxide (ZrO₂), titanium oxide (TiO₂), and magnesium oxide (MgO) as a main ingredient. The main ingredients of the first layer 32 and the second layer 34 refers to the material contained most in the first layer 32 and the second layer 34, respectively.

The reflective multilayer film 30 may only include at least one first layer 32 and at least one second layer 34, and the numbers of layers do not particularly matter. The total value of the numbers of layers of the first layers 32 and second layers 34 may be an odd number or may be an even number. In the layers in the reflective multilayer film 30, the layer in contact with the piezoelectric body 6 is the first layer 32, and the layer in contact with the cohesion layer 28 may be either the first layer 32 or the second layer 34.

For example, the reflective multilayer film 30 may include 3 layers or more and 12 layers or less of the first layers 32 and the second layers 34 in total. However, the reflective multilayer film 30 may include only one layer each of the first layer 32 and the second layer 34. The cohesion layer 28 may be formed also between each of the first layer 32 and the second layer 34 from the viewpoint of improving the adhesiveness of each layer of the reflective multilayer film 30 and reducing diffusion of the elastic wave in the reflective multilayer film 30.

As illustrated in FIG. 2, each of the first layers 32 may have a constant thickness D32, and each of the second layers 34 may have a constant thickness D34. The thickness D32 and the thickness D34 may be, for example, about 0.2 times the first pitch PA, and may be appropriately determined in a range of about 0.1 times to 2 times.

Protective Film

As illustrated in FIG. 2, the elastic wave resonator 4 according to the present embodiment includes the protective film 38 positioned so as to cover the uppermost surface of the elastic wave resonator 4. In other words, the elastic wave resonator 4 according to the present embodiment includes the protective film 38 positioned so as to cover the upper surface of the piezoelectric body 6 and the upper surface and the side surface of each of the IDT electrode 8 and the reflector 18.

The protective film 38 is a thin film used to protect the electrode on the piezoelectric body 6, for example, to reduce corrosion of the IDT electrode 8 and the reflector 18. For example, tetraethoxysilane ((TEOS): Si(OC₂H₅)₄) may be used for the protective film 38. In addition, SiO₂, Si₃N₄, or the like may be used for the protective film 38. The protective film 38 may include a plurality of laminated layers each made of the above-described material. The material described above has high insulating properties and low mass, and thus may be included in the protective film 38. However, the material of the protective film 38 is not limited thereto. The protective film 38 has a thickness D38, and the thickness D38 may be, for example, about 130 Å. The protective film 38 may have distribution in thickness in the plane of the elastic wave resonator 4, or may be formed substantially uniformly.

Effects of Elastic Wave Resonator In the elastic wave resonator 4 according to the present embodiment, the main resonance mode of the plate wave is the A1 mode. In the elastic wave resonator 4 according to the present embodiment, the second pitch PB is larger than the first pitch PB, or the duty ratio of the strip electrode 22 is higher than the duty ratio of the first electrode finger 14A. In addition, in the elastic wave resonator 4 according to the present embodiment, the gap G is larger than the first pitch PA.

With the above configuration, the elastic wave resonator 4 according to the present embodiment can reduce the intensity of the elastic wave excited in the piezoelectric body 6 in the spurious mode, based on the newly found finding described above. Thus, the elastic wave resonator 4 according to the present embodiment can improve the characteristics of the elastic wave excited in the piezoelectric body 6.

The elastic wave resonator 4 according to the present embodiment can more efficiently improve the characteristics of the elastic waves excited in the piezoelectric body 6 by appropriately designing the dimensions or materials of each component. More specifically, with the above design, the elastic wave resonator 4 according to the present embodiment can increase or maintain the intensity of the elastic wave excited in the piezoelectric body 6 in the main resonance mode while reducing the intensity of the elastic wave excited in the spurious mode.

The newly found finding described above will be described in detail in the following evaluation of the characteristics of the elastic wave resonator according to each example. In addition, a searching method for the design in the elastic wave resonator 4 according to the present embodiment will also be described.

Evaluation of Characteristics of Elastic Wave Resonator

Hereinafter, characteristics of the elastic wave resonators according to Examples 1 to 5 of the present disclosure will be evaluated. Here, a spurious index T expressed by the following equation is used to evaluate the intensity of the elastic wave excited in the spurious mode of the elastic wave resonator according to each example.

$$T = \frac{{\int }_{fr}^{fa} \sqrt{{( \frac{d P}{d f} )}^{2}} df}{df} \qquad Math [ 1 ]$$

Here, f represents an elastic wave frequency, fr represents the main resonance elastic wave frequency, and fa represents the antiresonance elastic wave frequency. P represents the phase of the elastic wave. Thus, the spurious index T indicates the intensity of the phase of the elastic wave excited in the spurious mode, from the main resonance elastic wave frequency to the antiresonance elastic wave frequency. It is found that the smaller the index T is, the more the elastic wave resonator in which the index T is measured reduces the intensity of the elastic wave excited in the spurious mode, and the more the characteristics are improved.

### Example 1

Configuration of Elastic Wave Resonator in Example 1

The elastic wave resonator according to the present example has the same configuration as the elastic wave resonator 4 according to the present embodiment. Here, A1 is used as the material of the electrode finger 14 and the strip electrode 22 in the elastic wave resonator according to the present example. The thickness D14 of the electrode finger 14 and the thickness D22 of the strip electrode 22 are each 0.11 μm, and the duty ratio of the electrode finger 14 and the duty ratio of the strip electrode 22 are each 0.55. In the present example, the first pitch PA is 0.965 μm, and the total number of the electrode fingers 14 included in the IDT electrode 8 is 51.

In the present example, lithium niobate is used for the piezoelectric body 6, and the thickness D6 of the piezoelectric body 6 is 0.376 μm. Si is used for the support substrate 26. In addition, SiO₂ is used for the first layer 32, the thickness D32 is 0.2 μm, HfO₂ is used for the second layer 34, and the thickness D34 is 0.16 μm. The protective film 38 is a TEOS thin film, and a thickness D36 is 130 Å.

Evaluation of Second Pitch in Example 1

In the present example, first, the magnitude of the second pitch PB is changed, and the ratio of the second pitch PB to the first pitch PA is changed, to calculate the characteristics of the elastic wave resonator according to the present embodiment by simulation.

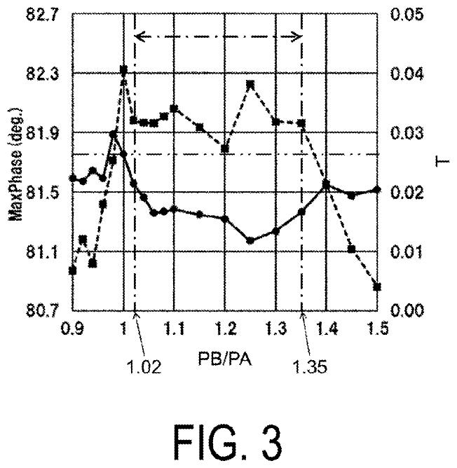

Calculation results of the above simulation are shown in the graph of FIG. 3. FIG. 3 is the graph showing the relationship among the ratio of the second pitch PB to the first pitch PA, the maximum phase, and the spurious index T, for the elastic wave resonator according to the present example.

In the graph of FIG. 3, the solid line indicates the spurious index T in the elastic wave resonator according to the present example for each ratio of the second pitch PB to the first pitch PA. In the graph of FIG. 3, the dotted line indicates the maximum value of the phase of impedance in the elastic wave resonator according to the present example for each ratio of the second pitch PB to the first pitch PA.

In the graph of FIG. 3, the left vertical axis represents the maximum value (unit: deg) of the phase of impedance, and the right vertical axis represents the spurious index T. The horizontal axis in FIG. 3 represents a value obtained by dividing the second pitch PB by the first pitch PA. In other words, when the first pitch PA and the second pitch PB are the same value, the value on the horizontal axis in FIG. 3 is 1, and as the second pitch PB increases with respect to the first pitch PA, the value on the horizontal axis in FIG. 3 increases. For comparison, the graph of FIG. 3 also shows the case where the second pitch PB is equal to or less than the first pitch PA.

Here, the graph of FIG. 3 shows, by two-dot chain lines, the value of the spurious index T when the first pitch PA and the second pitch PB are the same value. As is clear from the graph of FIG. 3, in the present example, when the second pitch PB is larger than the first pitch PA, the spurious index T is lower than when the first pitch PA and the second pitch PB are the same value. In other words, in the present example, it is found that when the second pitch PB is larger than the first pitch PA, the intensity of the elastic wave excited in the spurious mode is reduced.

From the simulation results shown in the graph of FIG. 3, the range of the ratio of the second pitch PB to the first pitch PA in which the maximum value of the phase of impedance is not significantly different from when the first pitch PA and the second pitch PB are the same value is searched.

First, when the second pitch PB is less than the first pitch PA, a case where the maximum value of the phase of impedance is closest as compared with the case where the first pitch PA and the second pitch PB are the same value is determined, and the maximum value is set as a reference value. When the second pitch PB is larger than the first pitch PA, the range of the ratio of the second pitch PB to the first pitch PA at which the maximum value of the phase of impedance exceeds the reference value is searched.

The range determined by the above search method is a range of the ratio of the second pitch PB to the first pitch PA in which the maximum value of the phase of impedance is not significantly different from when the first pitch PA and the second pitch PB are the same value. Specifically, in FIG. 3, the range of the ratio of the second pitch PB to the first pitch PA is searched with the maximum value, as a reference value, of the phase of impedance when the second pitch PB is 0.98 times the first pitch PA.

As a result, it is found that the maximum value of the phase of impedance is not significantly different from when the first pitch PA and the second pitch PB are the same value in the range indicated by the dashed line double-headed arrow in FIG. 3. Specifically, when the second pitch PB is 1.02 times or more and 1.35 times or less the first pitch PA, the maximum value of the phase of impedance does not significantly decrease as compared with when the first pitch PA and the second pitch PB are the same value.

As described above, in the present example, from the viewpoint of reducing the intensity of the elastic wave excited in the spurious mode, the second pitch PB may be larger than the first pitch PA. In addition, in the present example, from the viewpoint of maintaining the intensity of the elastic wave excited in the main resonance mode, the second pitch PB may be 1.02 times or more and 1.35 times or less the first pitch PA.

Evaluation of Gap in Example 1

The magnitude of the gap G and the number of the second electrode fingers 14B are changed, to calculate the characteristics of the elastic wave resonator according to the present embodiment by simulation. In the calculation, the second pitch PB is calculated while changing the value of the second pitch PB with respect to the first pitch PA in the above range, specifically, in a range of 1.02 times or more and 1.35 times or less.

As a result, it is found that when the second pitch PB is 1.06 times the first pitch PA, and when the gap G is larger than the first pitch PA, the spurious index T is lower than when the first pitch PA and the gap G are the same value. Thus, in the present example, it is found that the second pitch PB may be 1.06 times the first pitch PA.

In this manner, the value of the ratio of the second pitch PB to the first pitch PA may be determined from the behavior of the spurious index T when the ratio of the gap G to the first pitch PA is changed.

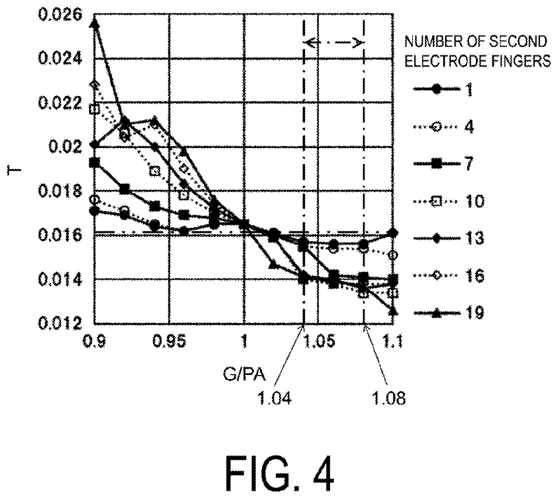

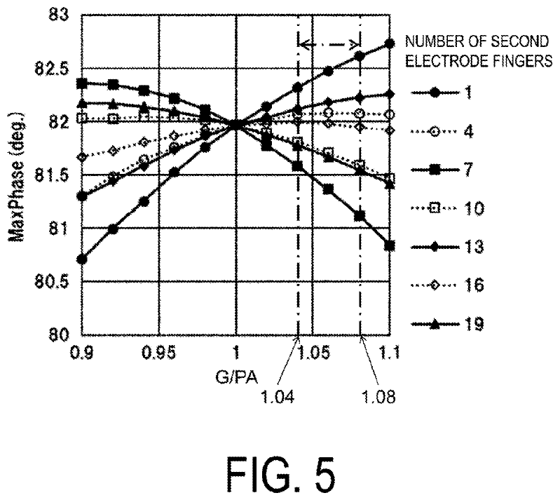

Calculation results of the above simulation when the second pitch PB is 1.06 times the first pitch PA are shown in the graphs of FIGS. 4 and 5.

Hereinafter, the “number of second electrode fingers” in each example indicates the number of the second electrode fingers 14B formed on one end side of the first electrode finger 14A in the propagation direction TD in the elastic wave resonator according to each example. In each example, the same number of the second electrode fingers 14B are formed at each end of the first electrode finger 14A in the propagation direction TD. Therefore, in each example, the total number of the second electrode fingers is twice the “number of second electrode fingers” described below.

FIG. 4 is a graph showing the relationship among the ratio of the gap G to the first pitch PA, the spurious index T, and the number of the second electrode fingers 14B, for the elastic wave resonator according to the present example. The graph of FIG. 4 shows the spurious index T in the elastic wave resonator according to the present example for each ratio of the gap G to the first pitch PA. The graph of FIG. 4 shows the spurious index T by changing the line type according to the number of the second electrode fingers 14B in the elastic wave resonator according to the present example.

In the graph of FIG. 4, the vertical axis represents the spurious index T. The horizontal axis in FIG. 4 represents the value obtained by dividing the gap G by the first pitch PA. In other words, when the first pitch PA and the gap G are the same value, the value on the horizontal axis in FIG. 4 is 1, and as the gap G increases with respect to the first pitch PA, the value on the horizontal axis in FIG. 4 increases. For comparison, the graph of FIG. 4 also shows the case where the gap G is equal to or less than the first pitch PA.

As is clear from the graph of FIG. 4, in the present example, it is found that when the gap G is larger than the first pitch PA, the spurious index T is lower than when the first pitch PA and the gap G are the same value. In other words, in the present example, it is found that when the gap G is larger than the first pitch PA, the intensity of the elastic wave excited in the spurious mode decreases.

The graph of FIG. 4 shows, by the two-dot chain line, the minimum value of the spurious index T when the gap G is equal to or less than the first pitch PA. Here, from the simulation results shown in the graph of FIG. 4, regardless of the number of the second electrode fingers 14B, the range of the ratio of the gap G to the first pitch PA in which the spurious index T is smaller than when the gap G is equal to or less than the first pitch PA is searched.

As a result, it is found that the spurious index T is lower than the minimum value of the spurious index T when the gap G is equal to or less than the first pitch PA regardless of the number of the second electrode fingers 14B in the range indicated by the dashed line double-headed arrow in FIG. 4. Specifically, when the gap G is 1.04 times or more and 1.08 times or less the first pitch PA, the spurious index T is lower than the minimum value of the spurious index T when the gap G is the first pitch PA or less.

Evaluation of the Number of Second Electrode Fingers in Example 1

FIG. 5 is a graph showing the relationship among the ratio of the gap G to the first pitch PA, the maximum phase, and the number of second electrode fingers 14B, for the elastic wave resonator according to the present example. The graph of FIG. 5 shows the maximum value of the phase of impedance in the elastic wave resonator according to the present example for each ratio of the gap G to the first pitch PA. The graph of FIG. 5 shows the maximum value of the phase of impedance by changing the line type according to the number of the second electrode fingers 14B in the elastic wave resonator according to the present example. For comparison the graph of FIG. 5 also shows the case where the gap G is equal to or less than the first pitch PA.

The graph of FIG. 5 shows, by the dashed line double-headed arrow, the range of the ratio of the gap G to the first pitch PA in which the spurious index T is smaller than when the gap G is equal to or less than the first pitch PA, which has been searched in the graph of FIG. 4. Here, in the range, the number of second electrode fingers 14B is searched, in which the maximum value of the phase of impedance does not significantly decrease, as compared with when the first pitch PA and the gap G are the same value. Specifically, the number of the second electrode fingers 14B that are not decreased by 0.2° or more when the gap G is 1.1 times the first pitch PA than when the first pitch PA and the gap G are the same value is searched.

As a result, it is found from the graph of FIG. 5 that when the number of the second electrode fingers 14B is 1, 4, 13, or 16, the maximum value of the phase of impedance does not significantly decrease as compared with when the first pitch PA and the gap G are the same value in the above-described range. In particular, it is found that when the number of the second electrode fingers 14B is 1 or 13, by making the gap G wider than the first pitch PA, the maximum value of the phase of impedance increases than when the gap G is equal to or less than the first pitch PA.

In consideration together with the graph of FIG. 4, it is found that the number of second electrode fingers 14B may be 13 from the viewpoint of increasing the maximum value of the phase of impedance while reducing the spurious index T. From the graph of FIG. 4, it is found that when the number of the second electrode fingers 14B is 13, the gap G may be 1.06 times the first pitch PA from the viewpoint of reducing the spurious index T.

Here, as long as referring to the graph of FIG. 4, it is found that when the number of second electrode fingers 14B is 1 or 4, the spurious index T may be reduced even when the gap G is smaller than the first pitch PA. However, referring to the graph of FIG. 5, it is found that when the number of second electrode fingers 14B is 1 or 4 and the gap G is smaller than the first pitch PA, the maximum value of the phase of impedance greatly decreases. Also from the above viewpoint, the gap G may be larger than the first pitch PA in the present example.

Design and Evaluation of Elastic Wave Resonator in Example 1 From the above, the design of the elastic wave resonator according to the present example has been found. Specifically, in the design of the elastic wave resonator according to the present example, the second pitch PB is 1.06 times the first pitch PA, the gap G is 1.06 times the first pitch PA, and the number of the second electrode fingers 14B is 13.

The characteristics of the elastic wave resonators, designed as described above, according to the present example are evaluated in comparison with the characteristics of the elastic wave resonators according to Comparative Examples 1 and 2.

In comparison with the elastic wave resonator according to the present example, the elastic wave resonator according to Comparative Example 1 is different only in that the second pitch PB and the gap G are the same values as the first pitch PA. Thus, it can be said that in the elastic wave resonator according to Comparative Example 1, all the electrode fingers 14 of the IDT electrode 8 are the first electrode fingers 14A.

In comparison with the elastic wave resonator according to the present example, the elastic wave resonator according to Comparative Example 2 is different only in that the gap G is 0.94 times the first pitch PA. In other words, the gap G of the elastic wave resonator according to Comparative Example 2 is smaller than the first pitch PA.

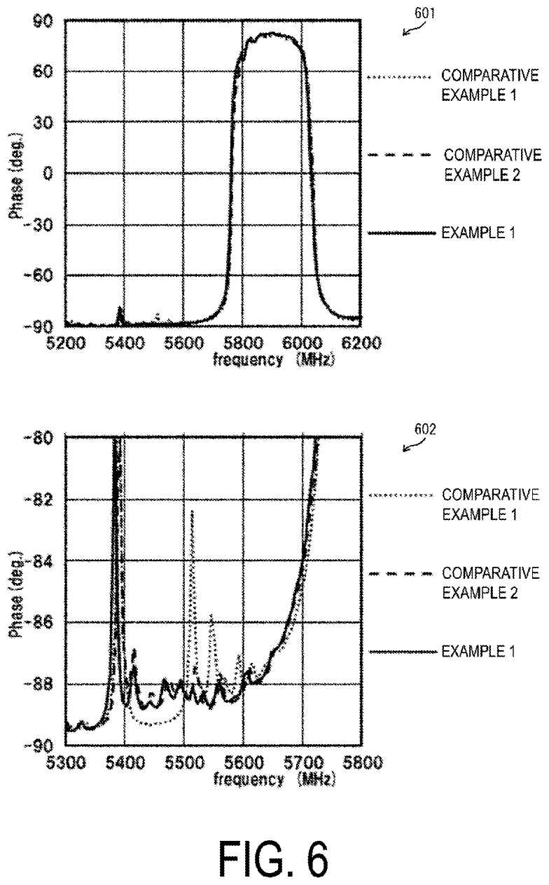

The characteristics of the elastic wave resonators, designed as described above, according to the present example are calculated by simulation, and shown in the graph of FIG. 6 together with the characteristics of the elastic wave resonators according to Comparative Examples 1 and 2. The graph of FIG. 6 is a graph showing, for each frequency, calculation results by simulation of the intensity of the elastic waves oscillated in the elastic wave resonators according to Example 1, Comparative Example 1, and Comparative Example 2. In the graph of FIG. 6, the vertical axis represents the phase (unit: deg), and the horizontal axis represents the frequency (unit: MHz).

The graph of FIG. 6 shows the characteristics of the elastic wave resonators according to Example 1, Comparative Example 1, and Comparative Example 2 by the solid line, the dotted line, and the broken line, respectively. In the graphs of FIG. 6, a graph 602 is an enlarged graph of frequencies from 5300 MHz to 5800 MHz and phases from −90 degrees to −80 degrees in a graph 601.

As is clear from the graph 601, even compared with the elastic wave resonator according to each comparative example, the elastic wave resonator according to Example 1 has no significant decrease in the intensity of the elastic wave excited in the main resonance and anti-main resonance modes. On the other hand, as is clear from the graph 602, as compared with the elastic wave resonator according to each comparative example, the elastic wave resonator according to Example 1 reduces the intensity of the elastic wave excited in the spurious mode.

Specifically, for example, the elastic wave resonator according to Example 1 reduces the intensity of the elastic wave having a frequency around 5510 MHz and around 5550 MHz as compared with the elastic wave resonator according to Comparative Example 1. The elastic wave resonator according to Example 1 reduces the intensity of the elastic wave having a frequency around 5420 MHz and around 5520 MHz as compared with the elastic wave resonator according to Comparative Example 1. All the elastic waves excited at the above frequencies correspond to the elastic waves excited in the spurious mode.

Thus, as is clear from the graph of FIG. 6, the elastic wave resonator with the design according to Example 1 reduces the intensity of the elastic wave excited in the spurious mode as compared with the elastic wave resonator according to each comparative example. In addition, the elastic wave resonator designed according to Example 1 maintains the intensity of the elastic wave excited in the main resonance and anti-main resonance modes as compared with the elastic wave resonator according to each comparative example.

### Example 2

Configuration of Elastic Wave Resonator in Example 2

The elastic wave resonator according to the present example is different from the elastic wave resonator 4 according to the previous example only in that the total number of the electrode fingers 14 included in the IDT electrode 8 is 101. In other words, the elastic wave resonator according to the present example has the same configuration as the elastic wave resonator 4 according to the previous example, other than the total number of the electrode fingers 14 included in the IDT electrode 8.

Evaluation of Second Pitch in Example 2

In the present example, first, the magnitude of the second pitch PB is changed, and the ratio of the second pitch PB to the first pitch PA is changed, to calculate, by simulation, the characteristics of the elastic wave resonator according to the present embodiment.

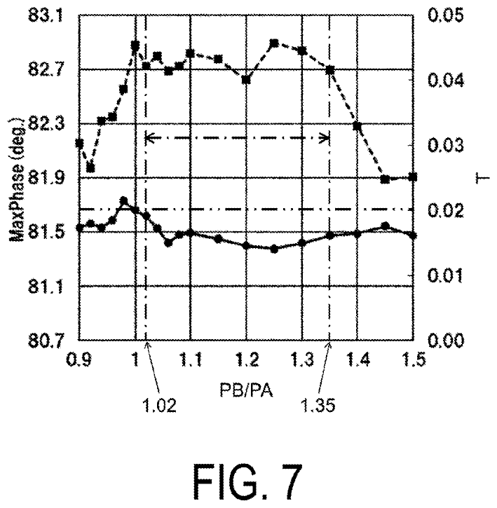

Calculation results of the above simulation are shown in the graph of FIG. 7. FIG. 7 is a graph showing the relationship among the ratio of the second pitch PB to the first pitch PA, the maximum phase, and the spurious index T, for the elastic wave resonator according to the present example. The axis and line type in the graph of FIG. 7 respectively correspond to the axis and line type in the graph of FIG. 3.

Here, the graph of FIG. 7 shows, by the two-dot chain line, the value of the spurious index T when the first pitch PA and the second pitch PB are the same value. As is clear from the graph of FIG. 7, in the present example, it is found that when the second pitch PB is larger than the first pitch PA, the spurious index T is lower than when the first pitch PA and the second pitch PB are the same value. In other words, in the present example, it is found that when the second pitch PB is larger than the first pitch PA, the intensity of the elastic wave excited in the spurious mode is reduced.

From the simulation results shown in the graph of FIG. 7, the range of the ratio of the second pitch PB to the first pitch PA in which the maximum value of the phase of impedance is not significantly different from when the first pitch PA and the second pitch PB are the same value is searched. As a result, it is found that the maximum value of the phase of impedance is not significantly different from when the first pitch PA and the second pitch PB are the same value in the range indicated by the dashed line double-headed arrow in FIG. 7. Specifically, when the second pitch PB is 1.02 times or more and 1.35 times or less the first pitch PA, the maximum value of the phase of impedance does not significantly decrease as compared with when the first pitch PA and the second pitch PB are the same value.

As described above, in the present example, from the viewpoint of reducing the intensity of the elastic wave excited in the spurious mode, the second pitch PB may be larger than the first pitch PA. In addition, in the present example, from the viewpoint of maintaining the intensity of the elastic wave excited in the main resonance mode, the second pitch PB may be 1.02 times or more and 1.35 times or less the first pitch PA.

From the above analysis, it is found that the characteristics of the elastic wave resonator according to the present example are not significantly different from the characteristics of the elastic wave resonator according to the previous example. In other words, it is found that the characteristics of the elastic wave resonator 4 according to the present embodiment are not greatly affected by the total number of the electrode fingers 14 of the IDT electrode 8.

Evaluation of Gap in Example 2 The magnitude of the gap G and the number of the second electrode fingers 14B are changed to calculate the characteristics of the elastic wave resonator according to the present embodiment by simulation. In the calculation, the second pitch PB is calculated while changing the value of the second pitch PB with respect to the first pitch PA in the above range, specifically, in a range of 1.02 times or more and 1.35 times or less.

As a result, it is found that when the second pitch PB is 1.06 times the first pitch PA, and when the gap G is larger than the first pitch PA, the spurious index T is lower than when the first pitch PA and the gap G are the same value. Thus, in the present example, it is found that the second pitch PB may be 1.06 times the first pitch PA.

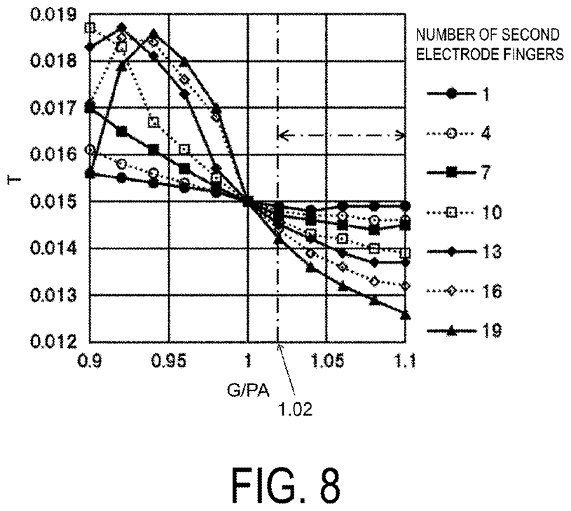

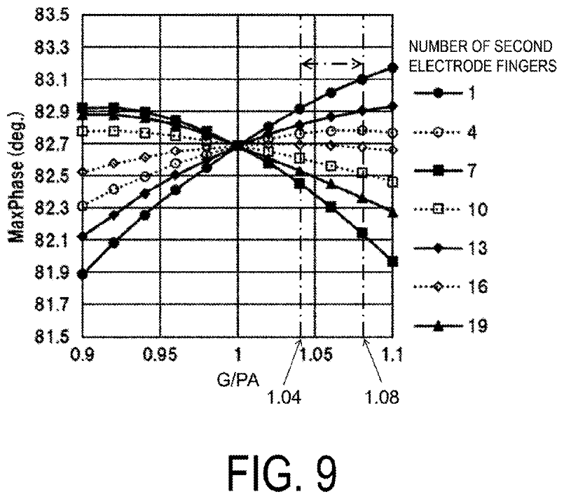

Calculation results of the above simulation when the second pitch PB is 1.06 times the first pitch PA are shown in the graphs of FIGS. 8 and 9. The axis and line type of each graph in FIGS. 8 and 9 respectively correspond to the axis and line type of each graph in FIGS. 4 and 5.

As is clear from the graph of FIG. 8, in the present example, it is found that when the gap G is larger than the first pitch PA, the spurious index T is lower than when the first pitch PA and the gap G are the same value. In other words, in the present example, it is found that when the gap G is larger than the first pitch PA, the intensity of the elastic wave excited in the spurious mode decreases.

The graph of FIG. 8 shows, by the two-dot chain line, the minimum value of the spurious index T when the gap G is equal to or less than the first pitch PA. Here, from the simulation results shown in the graph of FIG. 8, regardless of the number of the second electrode fingers 14B, the range of the ratio of the gap G to the first pitch PA in which the spurious index T is smaller than when the gap G is equal to or less than the first pitch PA is searched.

As a result, it is found that the spurious index T is lower than the minimum value of the spurious index T when the gap G is equal to or less than the first pitch PA regardless of the number of the second electrode fingers 14B in the range indicated by the dashed line double-headed arrow in FIG. 8. Specifically, when the gap G is 1.02 times or more and 1.1 times or less the first pitch PA, the spurious index T is lower than the minimum value of the spurious index T when the gap G is the first pitch PA or less.

From the analysis results of the graph of FIG. 7 and the graph of FIG. 8, it is found that there is no large difference between the elastic wave resonator according to the present example and the elastic wave resonator according to the previous example also in terms of the characteristics shown in the graph of FIG. 8. Therefore, in the present example, it is found that the gap G may be 1.04 times or more and 1.08 times or less the first pitch PA in the range of the ratio of the gap G to the first pitch PA.

Evaluation of the Number of Second Electrode Fingers in Example 2 The graph of FIG. 9 shows, by the dashed line double-headed arrow, the range of the ratio of the gap G to the first pitch PA described above. Here, in the range, the number of second electrode fingers 14B is searched, in which the maximum value of the phase of impedance does not significantly decrease, as compared with when the first pitch PA and the gap G are the same value.

As a result, it is found from the graph of FIG. 9 that when the number of the second electrode fingers 14B is 1, 4, 13, or 16, the maximum value of the phase of impedance does not significantly decrease as compared with when the first pitch PA and the gap G are the same value in the above-described range. In particular, it is found that when the number of the second electrode fingers 14B is 1 or 13, by making the gap G wider than the first pitch PA, the maximum value of the phase of impedance increases than when the gap G is equal to or less than the first pitch PA.

In consideration together with the graph of FIG. 8, it is found that the number of second electrode fingers 14B may be 13 from the viewpoint of increasing the maximum value of the phase of impedance while reducing the spurious index T. From the graph of FIG. 8, it is found that when the number of the second electrode fingers 14B is 13, the gap G may be 1.06 times the first pitch PA from the viewpoint of reducing the spurious index T.

Design and Evaluation of Elastic Wave Resonator in Example 2 From the above, the design of the elastic wave resonator according to the present example has been found. Specifically, in the design of the elastic wave resonator according to the present example, the second pitch PB is 1.06 times the first pitch PA, the gap G is 1.06 times the first pitch PA, and the number of the second electrode fingers 14B is 13.

The elastic wave resonator according to the present example designed as described above has the same configuration as that of the elastic wave resonator designed in the previous example. Therefore, it is found that the characteristics of the elastic wave resonator 4 according to the present embodiment do not greatly depend on the total number of the electrode fingers 14 of the IDT electrode 8.

The characteristics of the elastic wave resonators, designed as described above, according to the present example are evaluated in comparison with the characteristics of the elastic wave resonator according to Comparative Example 3.

In comparison with the elastic wave resonator according to the present example, the elastic wave resonator according to Comparative Example 3 is different only in that the second pitch PB and the gap G are the same values as the first pitch PA. Thus, it can be said that in the elastic wave resonator according to Comparative Example 3, all the electrode fingers 14 of the IDT electrode 8 are the first electrode fingers 14A.

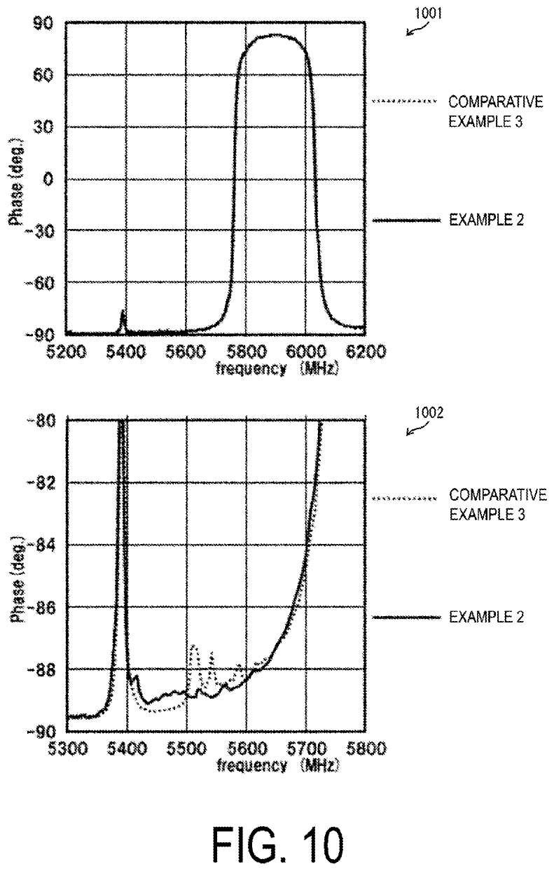

The characteristics of the elastic wave resonators, designed as described above, according to the present example are calculated by simulation, and shown in the graph of FIG. 10 together with the characteristics of the elastic wave resonator according to Comparative Example 3. The graph of FIG. 10 is a graph showing, for each frequency, calculation results by simulation of the intensity of the elastic waves oscillated in the elastic wave resonators according to Example 2 and Comparative Example 3. In the graph of FIG. 10, the vertical axis represents the phase (unit: deg), and the horizontal axis represents the frequency (unit: MHz).

The graph of FIG. 10 shows the characteristics of the elastic wave resonators according to Example 2 and Comparative Example 3, by the solid line and the dotted line, respectively. In the graphs of FIG. 10, a graph 1002 is an enlarged graph of frequencies from 5300 MHz to 5800 MHz and phases from −90 degrees to −80 degrees in a graph 1001.

As is clear from the graph 1001, even compared with the elastic wave resonator according to Comparative Example 3, the elastic wave resonator according to Example 2 has no significant decrease in the intensity of the elastic wave excited in the main resonance and anti-main resonance modes. On the other hand, as is clear from the graph 1002, as compared with the elastic wave resonator according to Comparative Example 3, the elastic wave resonator according to Example 2 reduces the intensity of the elastic wave excited in the spurious mode.

Specifically, for example, the elastic wave resonator according to Example 2 reduces the intensity of the elastic wave having a frequency around 5510 MHz, around 5540 MHz, around 5590 MHz, and the like as compared with the elastic wave resonator according to Comparative Example 3. All the elastic waves excited at the above frequencies correspond to the elastic waves excited in the spurious mode.

Thus, as is clear from the graph of FIG. 10, the elastic wave resonator with the design according to Example 2 reduces the intensity of the elastic wave excited in the spurious mode as compared with the elastic wave resonator according to Comparative Example 3. In addition, the elastic wave resonator designed according to Example 2 maintains the intensity of the elastic wave excited in the main resonance and anti-main resonance modes as compared with the elastic wave resonator according to Comparative Example 3.

### Example 3

Configuration of Elastic Wave Resonator in Example 3

The elastic wave resonator according to the present example differs from the elastic wave resonator according to Example 1 in the following points. Specifically, in the elastic wave resonator according to the present example, the duty ratio of the electrode finger 14 and the duty ratio of the strip electrode 22 are both 0.5. In the present example, the first pitch PA is 1.0488 μm. In the present example, the thickness D6 of the piezoelectric body 6 is 0.386 μm. Except for the above, the elastic wave resonator according to the present example has the same configuration as the elastic wave resonator according to Example 1.

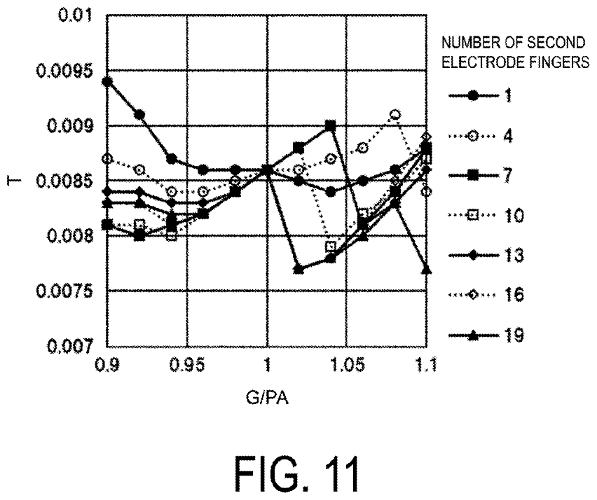

Evaluation of Gap in Example 3 In the present example, the magnitude of the gap G and the number of the second electrode fingers 14B are changed to calculate the characteristics of the elastic wave resonator according to the present embodiment by simulation. Here, it is presumed that by applying the values in the above-described examples also in the present example, even if the structures of the elastic wave resonators are different, the characteristics are improved also in the elastic wave resonator according to the present example in a range close to the range obtained by searching in the above-described examples. Thus, in the present example, the second pitch PB is 1.06 times the first pitch PA in the simulation. Calculation results of the above simulation are shown in the graph of FIG. 11. The axis and line type in the graph of FIG. 11 respectively correspond to the axis and line type in the graph of FIG. 4. For comparison, the graph of FIG. 11 also shows the case where the gap G is equal to or less than the first pitch PA.

As presented in the graph of FIG. 11, in the elastic wave resonator according to the present example, the spurious index T takes a relatively small value from about 0.008 to about 0.009 regardless of the ratio of the first pitch PA to the gap G. For this reason, the range for further reducing the spurious index T with respect to the ratio of the gap G to the first pitch PA is not easily determined.

Thus, in the present example, the design found in Example 1 is also adopted in the present example to evaluate the characteristics. Specifically, in the design of the elastic wave resonator according to the present example, the second pitch PB is 1.06 times the first pitch PA, the gap G is 1.06 times the first pitch PA, and the number of the second electrode fingers 14B is 13.

Evaluation of Elastic Wave Resonator in Example 3

The characteristics of the elastic wave resonators, designed as described above, according to the present example are evaluated in comparison with the characteristics of the elastic wave resonator according to Comparative Example 4.

In comparison with the elastic wave resonator according to the present example, the elastic wave resonator according to Comparative Example 4 is different only in that the second pitch PB and the gap G are the same values as the first pitch PA. Thus, it can be said that in the elastic wave resonator according to Comparative Example 4, all the electrode fingers 14 of the IDT electrode 8 are the first electrode fingers 14A.

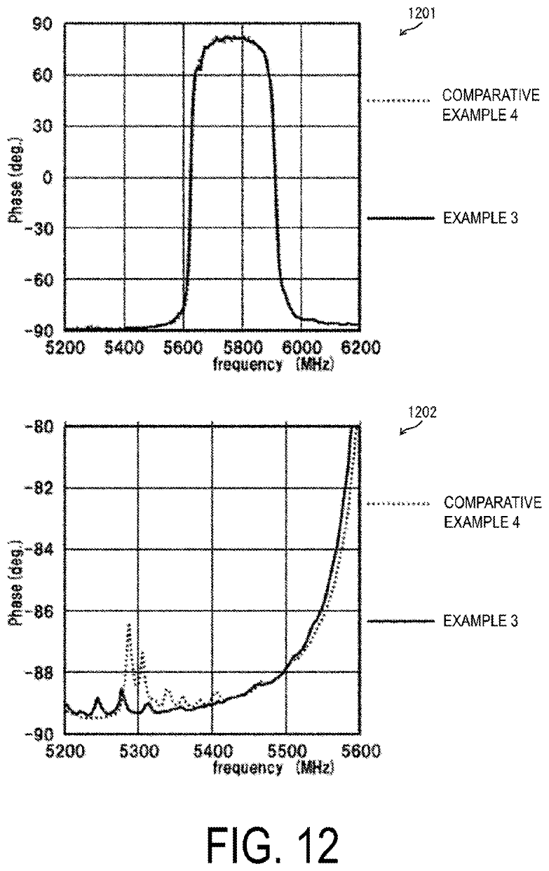

The characteristics of the elastic wave resonators, designed as described above, according to the present example are calculated by simulation, and presented in the graph of FIG. 12 together with the characteristics of the elastic wave resonator according to Comparative Example 4. The graph of FIG. 12 is a graph illustrating, for each frequency, calculation results by simulation of the intensity of the elastic waves oscillated in the elastic wave resonators according to Example 3 and Comparative Example 4. In the graph of FIG. 12, the vertical axis represents the phase (unit: deg), and the horizontal axis represents the frequency (unit: MHz).

The graph of FIG. 12 shows the characteristics of the elastic wave resonators according to Example 3 and Comparative Example 4, by the solid line and the dotted line, respectively. In the graphs of FIG. 12, a graph 1202 is an enlarged graph of frequencies from 5200 MHz to 5600 MHz and phases from −90 degrees to −80 degrees in a graph 1201.

As is clear from the graph 1201, even compared with the elastic wave resonator according to Comparative Example 4, the elastic wave resonator according to Example 3 has no significant decrease in the intensity of the elastic wave excited in the main resonance and anti-main resonance modes. On the other hand, as is clear from the graph 1202, as compared with the elastic wave resonator according to Comparative Example 4, the elastic wave resonator according to Example 3 reduces the intensity of the elastic wave excited in the spurious mode.

Specifically, for example, the elastic wave resonator according to Example 3 reduces the intensity of the elastic wave having a frequency from around 5290 MHz to around 5410 MHz as compared with the elastic wave resonator according to Comparative Example 4. All the elastic waves excited at the above frequencies correspond to the elastic waves excited in the spurious mode.

Thus, as is clear from the graph of FIG. 12, the elastic wave resonator with the design according to Example 3 reduces the intensity of the elastic wave excited in the spurious mode as compared with the elastic wave resonator according to Comparative Example 4. In addition, the elastic wave resonator designed according to Example 3 maintains the intensity of the elastic wave excited in the main resonance and anti-main resonance modes as compared with the elastic wave resonator according to Comparative Example 4.

### Example 4

Configuration of Elastic Wave Resonator in Example 4

The elastic wave resonator according to the present example differs from the elastic wave resonator according to Example 1 in the following points. Specifically, in the elastic wave resonator according to the present example, the thickness D14 of the electrode finger 14 and the thickness D22 of the strip electrode 22 are both 0.13 μm, and the duty ratio of the electrode finger 14 and the duty ratio of the strip electrode 22 are both 0.45. In the present example, the first pitch PA is 1.023 μm. In the present example, lithium tantalate is used for the piezoelectric body 6, and the thickness D6 of the piezoelectric body 6 is 0.414 μm. The thickness D34 of the second layer 34 is 0.17 μm. Except for the above, the elastic wave resonator according to the present example has the same configuration as the elastic wave resonator according to Example 1.

Evaluation of Second Pitch in Example 4 In the present example, first, the magnitude of the second pitch PB is changed, and then the ratio of the second pitch PB to the first pitch PA is changed, to calculate the characteristics of the elastic wave resonator according to the present embodiment by simulation.

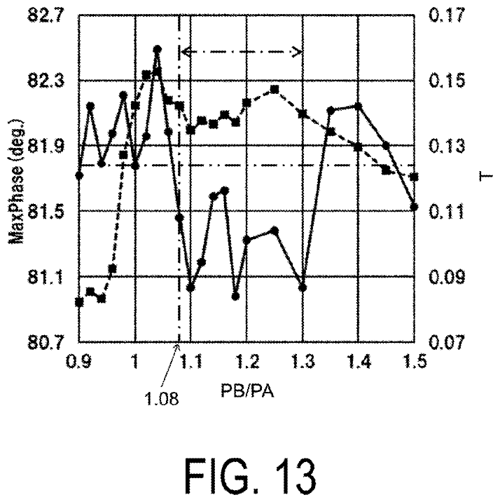

Calculation results of the above simulation are shown in the graph of FIG. 13. FIG. 13 is a graph showing the relationship among the ratio of the second pitch PB to the first pitch PA, the maximum phase, and the spurious index T, for the elastic wave resonator according to the present example. The axis and line type in the graph of FIG. 13 respectively correspond to the axis and line type in the graph of FIG. 3.

Here, the graph of FIG. 13 shows, by the two-dot chain line, the value of the spurious index T when the first pitch PA and the second pitch PB are the same value. As is clear from the graph of FIG. 13, in the present example, it is found that when the second pitch PB is 1.08 times or more and 1.3 times or less the first pitch PA, the spurious index T is lower than when the first pitch PA and the second pitch PB are the same value.

The above range is indicated by the dashed line double-headed arrow in FIG. 13. In the range, it is found that the maximum value of the phase of impedance is not significantly different from when the first pitch PA and the second pitch PB are the same value. Specifically, when the second pitch PB is 1.08 times or more and 1.3 times or less the first pitch PA, the maximum value of the phase of impedance does not significantly decrease as compared with when the first pitch PA and the second pitch PB are the same value.

As described above, in the present example, from the viewpoint of reducing the intensity of the elastic wave excited in the spurious mode, the second pitch PB may be 1.08 times or more and 1.3 times or less the first pitch PA. Also from the viewpoint of maintaining the intensity of the elastic wave excited in the main resonance mode, the second pitch PB may be 1.08 times or more and 1.3 times or less the first pitch PA.

Evaluation of Gap in Example 4

The magnitude of the gap G and the number of the second electrode fingers 14B are changed to calculate the characteristics of the elastic wave resonator according to the present embodiment by simulation. In the calculation, the second pitch PB is calculated while changing the value of the second pitch PB with respect to the first pitch PA in the above range, specifically, in a range of 1.08 times or more and 1.3 times or less.

As a result, it is found that when the second pitch PB is 1.12 times the first pitch PA, and when the gap G is larger than the first pitch PA, the spurious index T is lower than when the first pitch PA and the gap G are the same value. Thus, in the present example, it is found that the second pitch PB may be 1.12 times the first pitch PA.

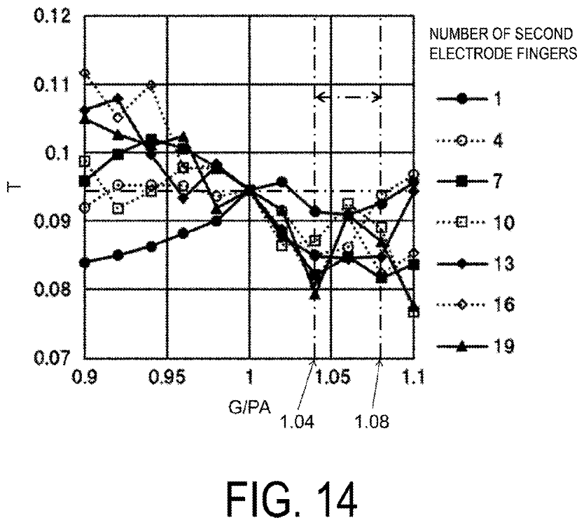

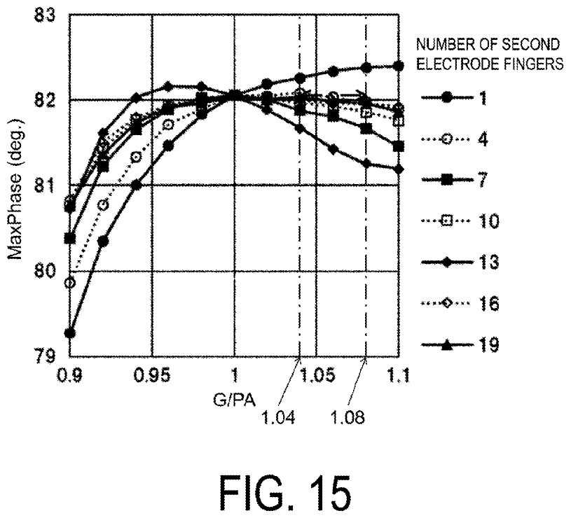

Calculation results of the above simulation when the second pitch PB is 1.12 times the first pitch PA are shown in the graphs of FIGS. 14 and 15. The axis and line type of each graph in FIGS. 14 and 15 respectively correspond to the axis and line type of each graph in FIGS. 4 and 5.

As is clear from the graph of FIG. 14, in the present example, it is found that when the gap G is larger than the first pitch PA, the spurious index T tends to be lower than when the first pitch PA and the gap G are the same value. In other words, in the present example, it is found that, depending on the number of second electrode fingers 14B, when the gap G is larger than the first pitch PA, the intensity of the elastic wave excited in the spurious mode decreases.

The graph of FIG. 14 shows, by the two-dot chain line, the minimum value of the spurious index T when the gap G is equal to or less than the first pitch PA. Here, from the simulation results shown in the graph of FIG. 14B, regardless of the number of the second electrode fingers 14, the range of the ratio of the gap G to the first pitch PA in which the spurious index T is smaller than when the gap G is equal to or less than the first pitch PA is searched.

As a result, it is found that the spurious index T is lower than the minimum value of the spurious index T when the gap G is equal to or less than the first pitch PA regardless of the number of the second electrode fingers 14B in the range indicated by the dashed line double-headed arrow in FIG. 14. Specifically, when the gap G is 1.04 times or more and 1.08 times or less the first pitch PA, the spurious index T is lower than the minimum value of the spurious index T when the gap G is the first pitch PA or less.

Evaluation of the Number of Second Electrode Fingers in Example 4

The graph of FIG. 15 shows, by the dashed line double-headed arrow, the range of the ratio of the gap G to the first pitch PA in which the spurious index T is smaller than when the gap G is equal to or less than the first pitch PA, which has been searched in the graph of FIG. 14. Here, in the range, the number of second electrode fingers 14B was searched, in which the maximum value of the phase of impedance does not significantly decrease, as compared with when the first pitch PA and the gap G are the same value.

As a result, it is found from the graph of FIG. 15 that when the number of the second electrode fingers 14B is 1, 4, 10, 16, or 19, the maximum value of the phase of impedance does not significantly decrease as compared with when the first pitch PA and the gap G are the same value in the above-described range.

In consideration together with the graph of FIG. 14, it is found that the number of second electrode fingers 14B may be 16 from the viewpoint of increasing the maximum value of the phase of impedance while reducing the spurious index T. From the graph of FIG. 14, it is found that when the number of the second electrode fingers 14B is 16, the gap G may be 1.06 times the first pitch PA from the viewpoint of reducing the spurious index T.

As long as, referring to the graph of FIG. 14, it is found that when the number of second electrode fingers 14B is 1, the spurious index T may be reduced even when the gap G is smaller than the first pitch PA. However, referring to the graph of FIG. 15, it is found that when the number of second electrode fingers 14B is 1 and the gap G is smaller than the first pitch PA, the maximum value of the phase of impedance greatly decreases. Also from the above viewpoint, it can be said that the gap G may be larger than the first pitch PA in the present example.

Design and Evaluation of Elastic Wave Resonator in Example 4 From the above, the design of the elastic wave resonator according to the present example has been found. Specifically, in the design of the elastic wave resonator according to the present example, the second pitch PB is 1.12 times the first pitch PA, the gap G is 1.06 times the first pitch PA, and the number of the second electrode fingers 14B is 16.

The characteristics of the elastic wave resonators, designed as described above, according to the present example are evaluated in comparison with the characteristics of the elastic wave resonator according to Comparative Example 5.

In comparison with the elastic wave resonator according to the present example, the elastic wave resonator according to Comparative Example 5 is different only in that the second pitch PB and the gap G are the same values as the first pitch PA. Thus, it can be said that in the elastic wave resonator according to Comparative Example 5, all the electrode fingers 14 of the IDT electrode 8 are the first electrode fingers 14A.

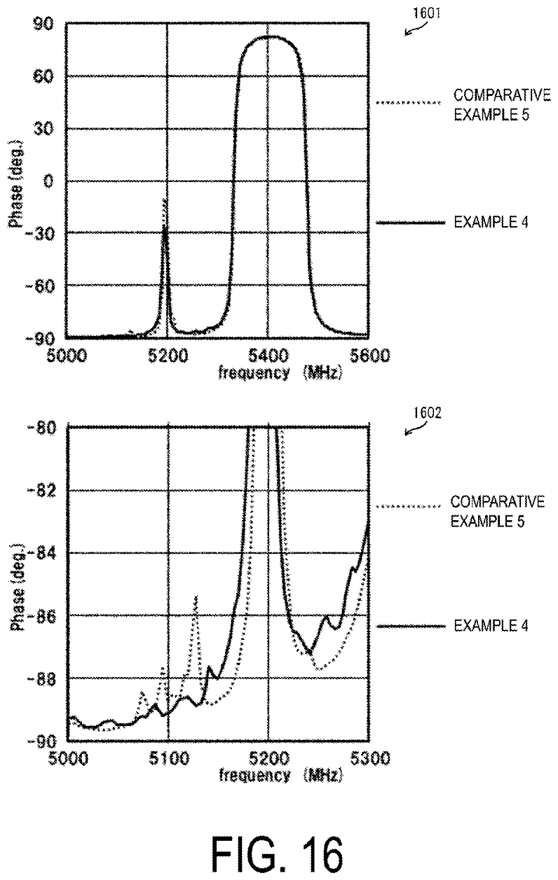

The characteristics of the elastic wave resonators, designed as described above, according to the present example are calculated by simulation, and presented in the graph of FIG. 16 together with the characteristics of the elastic wave resonator according to Comparative Example 5. The graph of FIG. 16 is a graph showing, for each frequency, calculation results by simulation of the intensity of the elastic waves oscillated in the elastic wave resonators according to Example 4 and Comparative Example 5. In the graph of FIG. 16, the vertical axis represents the phase (unit: deg), and the horizontal axis represents the frequency (unit: MHz).

The graph of FIG. 16 shows the characteristics of the elastic wave resonators according to Example 4 and Comparative Example 5, by the solid line and the dotted line, respectively. In the graphs of FIG. 16, a graph 1602 is an enlarged graph of frequencies from 5000 MHz to 5300 MHz and phases from −90 degrees to −80 degrees in a graph 1601.

As is clear from the graph 1601, even compared with the elastic wave resonator according to Comparative Example 5, the elastic wave resonator according to Example 4 has no significant decrease in the intensity of the elastic wave excited in the main resonance and anti-main resonance modes. On the other hand, as is clear from the graph 1602, as compared with the elastic wave resonator according to Comparative Example 5, the elastic wave resonator according to Example 4 reduces the intensity of the elastic wave excited in the spurious mode.

Specifically, for example, the elastic wave resonator according to Example 4 reduces the intensity of the elastic wave having a frequency from around 5200 MHz, around 5070 MHz to around 5130 MHz, and the like as compared with the elastic wave resonator according to Comparative Example 5. All the elastic waves excited at the above frequencies correspond to the elastic waves excited in the spurious mode.

Thus, as is clear from the graph of FIG. 16, the elastic wave resonator with the design according to Example 4 reduces the intensity of the elastic wave excited in the spurious mode as compared with the elastic wave resonator according to Comparative Example 5. In addition, the elastic wave resonator designed according to Example 4 maintains the intensity of the elastic wave excited in the main resonance and anti-main resonance modes as compared with the elastic wave resonator according to Comparative Example 5.

### Example 5

Configuration of Elastic Wave Resonator in Example 5

The elastic wave resonator according to the present example differs from the elastic wave resonator according to Example 1 in the following points. Specifically, in the elastic wave resonator according to the present example, the duty ratio of the electrode finger 14 is 0.55, but the duty ratio of the strip electrode 22 is larger than the duty ratio of the electrode finger 14. Except for the above, the elastic wave resonator according to the present example has the same configuration as the elastic wave resonator according to Example 1.

Evaluation of Duty Ratio of Strip Electrode in Example 5

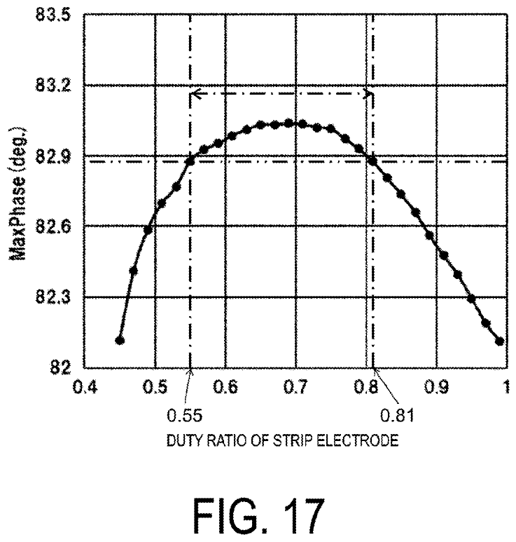

In the present example, first, the duty ratio of the strip electrode 22 is changed, and the characteristics of the elastic wave resonator according to the present embodiment are calculated by simulation. Calculation results of the above simulation are shown in the graph of FIG. 17. FIG. 17 is a graph showing the relationship between the duty ratio with the strip electrode 22 and the maximum phase, regarding the elastic wave resonator according to the present example.

The graph of FIG. 17 shows the maximum value of the phase of impedance in the elastic wave resonator according to the present example for each duty ratio of the strip electrode 22. In the graph of FIG. 17, the vertical axis represents the maximum value (unit: deg) of the phase of impedance, and the horizontal axis represents the duty ratio of the strip electrode 22. In other words, when the duty ratio of the electrode finger 14 and the duty ratio of the strip electrode 22 are the same value, the value of the horizontal axis in FIG. 17 is 0.55. For comparison, FIG. 17 also illustrates the case where the duty ratio of the strip electrode 22 is equal to or less than the duty ratio of the electrode finger 14.

Here, the graph of FIG. 17 shows, by the two-dot chain line, the maximum value of the phase of impedance when the duty ratio of the strip electrode 22 is 0.55, in other words, when the duty ratio of the electrode finger 14 and the duty ratio of the strip electrode 22 are the same value. As is clear from the graph of FIG. 17, in the present example, it is found that when the duty ratio of the strip electrode 22 is larger than 0.55, the maximum value of the phase of impedance may be higher than when the duty ratio of the strip electrode 22 is 0.55.

In other words, in the present example, it is found that when the duty ratio of the strip electrode 22 is larger than the duty ratio of the electrode finger 14, the intensity of the elastic wave excited in the main resonance mode can be increased in some cases.

In particular, in the present example, when the duty ratio of the strip electrode 22 is larger than 0.55 and less than 0.81, the maximum value of the phase of impedance increases as compared with the case where the duty ratio of the strip electrode 22 is 0.55. From the above, in the present example, it is found that the duty ratio of the strip electrode 22 may be 1.04 times or more and 1.43 times or less the duty ratio of either the first electrode finger 14A or the second electrode finger 14B.

Evaluation of Gap in Example 5

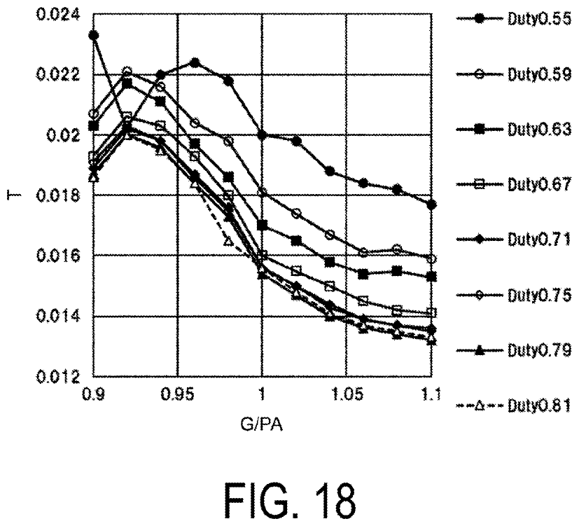

The magnitude of the gap G and the duty ratio of the strip electrode 22 are changed to calculate the characteristics of the elastic wave resonator according to the present embodiment by simulation. Calculation results of the above simulation are shown in the graph of FIG. 18.

FIG. 18 is a graph showing the relationship among the ratio of the gap G to the first pitch PA, the spurious index T, and the duty ratio of the strip electrode 22, for the elastic wave resonator according to the present example. The graph of FIG. 18 shows the spurious index T in the elastic wave resonator according to the present example for each ratio of the gap G to the first pitch PA. The graph of FIG. 18 shows the spurious index T by changing the line type according to the duty ratio of the strip electrode 22 in the elastic wave resonator according to the present example.

In the graph of FIG. 18, the vertical axis represents the spurious index T. The horizontal axis in FIG. 18 represents the value obtained by dividing the gap G by the first pitch PA. In other words, when the first pitch PA and the gap G are the same value, the value on the horizontal axis in FIG. 18 is 1, and as the gap G increases with respect to the first pitch PA, the value on the horizontal axis in FIG. 18 increases. For the elastic wave resonator, according to the present embodiment, whose characteristics is shown in the graph of FIG. 18, the number of the second electrode fingers 14B is 13, and the total number of the electrode fingers 14 included in the IDT electrode 8 is 101.

As is clear from the graph of FIG. 18, in the present example, it is found that when the gap G is larger than the first pitch PA and the duty ratio of the strip electrode 22 is from 0.55 to 0.81, the spurious index T decreases. In other words, in the present example, it is found that when the gap G is larger than the first pitch PA and the duty ratio of the strip electrode 22 is from 0.55 to 0.81, the intensity of the elastic wave excited in the spurious mode decreases.

As described above, in the present example, since the gap G is larger than the first pitch PA, the intensity of the elastic wave excited in the spurious mode decreases. In the present example, the duty ratio of the strip electrode 22 is 1.04 times or more and 1.43 times or less the duty ratio of either the first electrode finger 14A or the second electrode finger 14B, whereby the intensity of the elastic wave excited in the main resonance mode increases. Thus, the elastic wave resonator 4, designed as described above, according to the present example improves the characteristics of the elastic wave excited in the piezoelectric body 6.

### SUMMARY OF EXAMPLES

In any elastic wave resonator designed in each of the above-described examples, the second pitch PB is larger than the first pitch PB, or the duty ratio of the strip electrode 22 is higher than the duty ratio of the first electrode finger 14A. In the elastic wave resonator, the gap G is larger than the first pitch PA. In addition, in the elastic wave resonator, characteristics of the elastic wave excited are improved as compared with the elastic wave resonator according to each comparative example.

Thus, a result consistent with the above-described finding found in the elastic wave resonator that excites the plate wave in the A1 mode is obtained from the characteristics of the elastic wave resonator designed in each example. The elastic wave resonator according to each example is an elastic wave resonator that excites a plate wave in the A1 mode, and has different characteristics from the elastic wave resonator that excites a plate wave in a mode different from the A1 mode. Therefore, the above-described finding is not easily obtained from a known elastic wave resonator that excites a plate wave in a mode different from the A1 mode.

The characteristics of the elastic wave resonators according to several examples have been described above. However, the elastic wave resonators according to the above-described examples are merely examples, and various modifications are possible. Specifically, in the elastic wave resonator 4 according to the present embodiment, the second pitch PB is required to be wider than the first pitch PA, or the duty ratio of the strip electrode 22 is required to be higher than the duty ratio of the electrode finger 14. In addition, in the elastic wave resonator 4 according to the present embodiment, the gap G is required to be wider than the first pitch PA. The configuration of each member of the elastic wave resonator 4 according to the present embodiment can be variously changed within a range satisfying the above conditions. Even when the configuration of each member of the elastic wave resonator 4 according to the present embodiment is changed, the design of the elastic wave resonator 4 can be searched by the same method as any of the design search methods described in each example.

### Second Embodiment

Membrane Structure

Another embodiment of the present disclosure will be described below. For convenience of description, a member having the same function as that of a member described in the embodiments described above is denoted by the same reference sign, and description thereof will not be repeated.

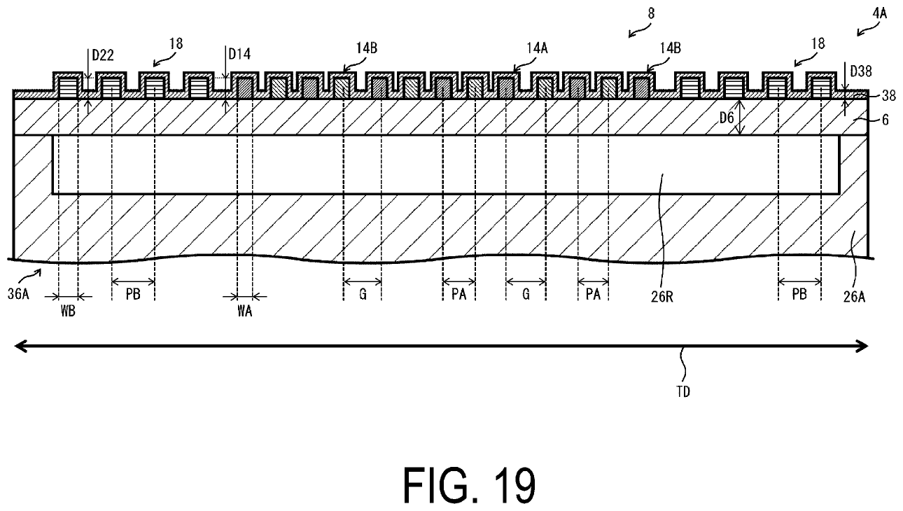

FIG. 19 is a schematic cross-sectional view of an elastic wave resonator 4A according to the present embodiment, and is a view illustrating a cross section corresponding to the cross section illustrated in FIG. 2.

As illustrated in FIG. 19, the elastic wave resonator 4A according to the present embodiment includes a support substrate 26A in place of the support substrate 26 as compared with the elastic wave resonator 4 according to the previous embodiment. The support substrate 26A has a recessed portion 26R in a position overlapping a part of a piezoelectric body 6 in plan view.

The support substrate 26A according to the present embodiment has a gap between the support substrate 26A and the piezoelectric body 6 at a position overlapping the recessed portion 26R in plan view. Thus, the piezoelectric body 6 according to the present embodiment has a part that is not directly supported by the support substrate 26A at a position overlapping the recessed portion 26R in plan view.

The elastic wave resonator 4A according to the present embodiment does not include the cohesion layer 28 and the reflective multilayer film 30 as compared with the elastic wave resonator 4 according to the previous embodiment. Thus, the support substrate 26A according to the present embodiment may directly support the piezoelectric body 6 on the peripheral side in the in-plane direction of the elastic wave resonator 4 relative to the recessed portion 26R.

As in the structure of the elastic wave resonator 4A according to the present embodiment, the structure in which the piezoelectric body 6 has a part not directly supported by the support substrate 26A may be referred to as a membrane structure.

Except for the above configuration, the elastic wave resonator 4A according to the present embodiment has the same configuration as the elastic wave resonator 4 according to the previous embodiment.

Also in the elastic wave resonator 4A according to the present embodiment, the elastic wave excited in the piezoelectric body 6 is an A1 mode longitudinal wave. Thus, also in the present embodiment, from the new finding discussed in the previous embodiment, the second pitch PB is wide, or the duty ratio of the strip electrode 22 is large, and the gap G is large, thereby reducing the elastic wave excited in the spurious mode. Thus, the elastic wave resonator 4 according to the present embodiment can improve the characteristics of the elastic wave excited in the piezoelectric body 6.

General Configuration of Communication Apparatus and Demultiplexer

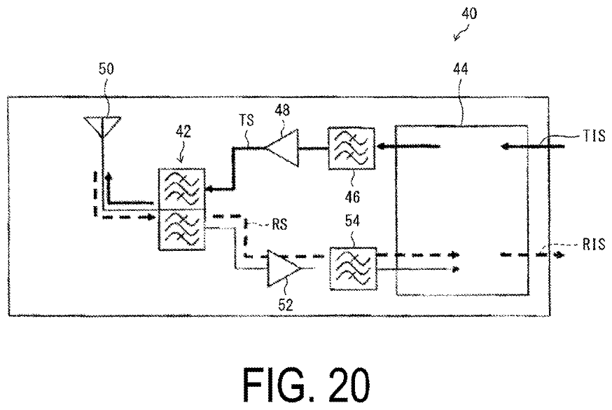

FIG. 20 is a block diagram illustrating a main part of a communication apparatus 40 according to the embodiments of the present disclosure. The communication apparatus 40 performs wireless communication using radio waves. A demultiplexer 42 has a function of demultiplexing a signal of a transmission frequency and a signal of a reception frequency in the communication apparatus 40.

In the communication apparatus 40, a transmission information signal TIS including information to be transmitted is subjected to modulation and an increase in frequency (conversion to a high-frequency signal of a carrier wave frequency) by an RF-IC 44 to become a transmission signal TS. The transmission signal TS is subjected to removal of unwanted components, which are components other than the components in the passband for transmission, by a band-pass filter 46, and is amplified by an amplifier 48 to be input to the demultiplexer 42. The demultiplexer 42 removes unwanted components, which are components other than the components in the passband for transmission, from the input transmission signal TS, and then outputs the transmission signal TS to an antenna 50. The antenna 50 converts the input electrical signal (transmission signal TS) to a wireless signal and transmits the converted signal.

In the communication apparatus 40, a wireless signal received by the antenna 50 is converted to an electrical signal (reception signal RS) by the antenna 50 to be input to the demultiplexer 42. The demultiplexer 42 removes unwanted components, which are components other than the components in the passband for reception, from the input reception signal RS, and then outputs the converted signal to an amplifier 52. The output reception signal RS is amplified by the amplifier 52, and is subjected to the removal of unwanted components, which are components other than the components in the passband for reception, by a band-pass filter 54. Then, the reception signal RS is subjected to a decrease in frequency and demodulation by the RF-IC 44 to become a reception information signal RIS.

The transmission information signal TIS and the reception information signal RIS are only required to be low-frequency signals (baseband signals) including appropriate information, and are, for example, analog sound signals or digitized sound signals. The passband of the wireless signal may be a passband in compliance with various standards such as Universal Mobile Telecommunications System (UMTS). The modulation scheme may be any of phase modulation, amplitude modulation, frequency modulation, or a combination of any two or more of them.

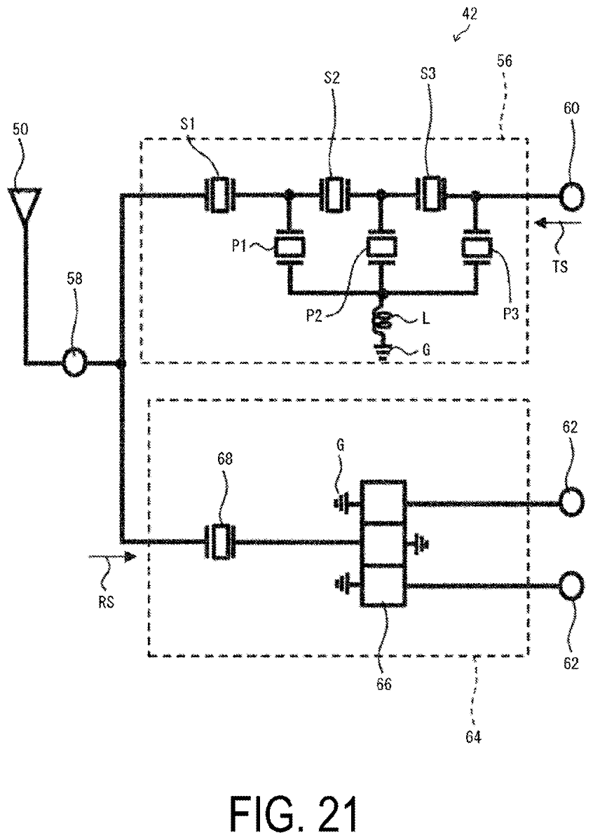

FIG. 21 is a circuit diagram illustrating the configuration of a demultiplexer 42 according to one embodiment of the present disclosure. The demultiplexer 42 is the demultiplexer 42 used in the communication apparatus 40 in FIG. 20.

As illustrated in FIG. 21, a transmission filter 56 includes series resonators S1 to S3 and parallel resonators P1 to P3. The demultiplexer 42 is mainly constituted of an antenna terminal 58, a transmission terminal 60, a reception terminal 62, the transmission filter 56 disposed between the antenna terminal 58 and the transmission terminal 60, and a reception filter 64 disposed between the antenna terminal 58 and the reception terminal 62. The transmission signal TS from the amplifier 48 is input to the transmission terminal 60, and the transmission signal TS input to the transmission terminal 60 is subjected to the removal of unwanted components, which are components other than the components in the passband for transmission, in the transmission filter 56 and is output to the antenna terminal 58. The reception signal RS from the antenna 50 is input to the antenna terminal 58, and is subjected to the removal of unwanted components, which are components other than the components in the passband for reception, in the reception filter 64 and is output to the reception terminal 62.

The transmission filter 56 includes, for example, a ladder elastic wave filter. Specifically, the transmission filter 56 includes three series resonators S1, S2, and S3 connected in series between the input side and the output side of the filter, and three parallel resonators P1, P2, and P3 provided between series arms which are wiring for connecting the series resonators to one another, and a reference potential portion G. That is, the transmission filter 56 is a three-stage ladder filter. However, the transmission filter 56 includes any number of stages of the ladder filter.

An inductor L is provided between the parallel resonators P1 to P3 and the reference potential portion G. By setting the inductance of the inductor L to a predetermined magnitude, an attenuation pole is formed outside the passband of the transmission signal to increase out-of-band attenuation. A plurality of series resonators S1 to S3 and a plurality of parallel resonators P1 to P3 are each made of an elastic wave resonator.

The reception filter 64 includes, for example, a multi-mode elastic wave filter 66, and an auxiliary resonator 68 connected in series to the input side of the multi-mode elastic wave filter 66. In the present embodiment, the multi-mode includes the double mode. The multi-mode elastic wave filter 66 has a balanced-unbalanced conversion function, and the reception filter 64 is connected to two reception terminals 62, to which balanced signals are output. The reception filter 64 is not limited to being constituted by the multi-mode elastic wave filter 66, and may be constituted by a ladder filter, or may be a filter that does not have a balanced-unbalanced conversion function.

A circuit for impedance matching including an inductor or the like may be inserted between the ground potential portion G and a connection point of the transmission filter 56, the reception filter 64, and the antenna terminal 58.

The elastic wave filter according to each of the above-described embodiments is an elastic wave element constituting at least one ladder filter circuit of the transmission filter 56 or the reception filter 64 in the demultiplexer 42 illustrated in FIGS. 20 and 21, for example. When either the transmission filter 56 or the reception filter 64 is the elastic wave filter according to each of the above-described embodiments, all or at least some of the elastic wave resonators included in the filter are the elastic wave resonators 4 or the elastic wave resonators 4A according to each of the above-described embodiments.

By adopting the demultiplexer 42 including the transmission filter 56 or the reception filter 64 described above, the filter characteristics of the communication apparatus 40 may be improved.

The invention according to the present disclosure has been described above based on the various drawings and examples. However, the invention according to the present disclosure is not limited to the embodiments described above. That is, the embodiments of the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, note that a person skilled in the art can easily make various variations or modifications based on the present disclosure. Note that these variations or modifications are included within the scope of the present disclosure.

### REFERENCE SIGNS

4, 4A Elastic wave resonator
6 Piezoelectric body
8 IDT electrode
12A First bus bar
12B Second bus bar
14 Electrode finger
14A First electrode finger
14B Second electrode finger
16 Dummy electrode
18 Reflector
22 Strip electrode
26, 26A Support substrate
26R Recessed portion
30 Reflective multilayer film
32 First layer
34 Second layer
40 Communication apparatus
42 Demultiplexer
44 RF-IC
50 Antenna
56 Transmission filter
58 Antenna terminal
64 Reception filter

1. An elastic wave resonator that excites a plate wave in an A1 mode in a piezoelectric body, the elastic wave resonator comprising:
the piezoelectric body;
an IDT electrode positioned on the piezoelectric body and comprising a plurality of first electrode fingers arranged at a first pitch in a propagation direction of an elastic wave, and at least one second electrode finger formed at respective ends in the propagation direction of the plurality of first electrode fingers; and
a pair of reflectors comprising a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being each positioned at respective one of ends in the propagation direction of the IDT electrode on the piezoelectric body.

2. (canceled)

3. An elastic wave resonator, comprising:
a support substrate;
a reflective multilayer film positioned on the support substrate;
a piezoelectric body positioned on an opposite side of the reflective multilayer film from the support substrate;
an IDT electrode positioned on the piezoelectric body on an opposite side from the support substrate and comprising a plurality of first electrode fingers arranged at a first pitch in a propagation direction of an elastic wave, and at least one second electrode finger formed at respective ends in the propagation direction of the plurality of first electrode fingers; and
a pair of reflectors comprising a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being each positioned at respective one of ends in the propagation direction of the IDT electrode on the piezoelectric body.

4. An elastic wave resonator, comprising:
a piezoelectric body;
a support substrate supporting the piezoelectric body, comprising a recessed portion at a position overlapping a part of the piezoelectric body in plan view, and comprising a gap between the support substrate and the piezoelectric body at a position overlapping the recessed portion in plan view;
an IDT electrode positioned on the piezoelectric body on an opposite side from the support substrate and comprising a plurality of first electrode fingers arranged at a first pitch in a propagation direction of an elastic wave, and at least one second electrode finger formed at respective ends in the propagation direction of the plurality of first electrode fingers; and
a pair of reflectors comprising a plurality of strip electrodes arranged, in the propagation direction, at a second pitch wider than the first pitch, or a plurality of strip electrodes having a duty ratio higher than a duty ratio of any of the plurality of first electrode fingers and the at least one second electrode finger, the pair of reflectors being each positioned at respective one of ends in the propagation direction of the IDT electrode on the piezoelectric body.

5. The elastic wave resonator according to claim 1, wherein the at least one second electrode finger is formed at respective ends in the propagation direction of the plurality of first electrode fingers with a gap wider than the first pitch.

6. The elastic wave resonator according to claim 1, wherein
the piezoelectric body contains lithium niobate, and
the second pitch is 1.02 times or more and 1.35 times or less the first pitch.

7. The elastic wave resonator according to claim 1, wherein
the piezoelectric body contains lithium tantalate, and
the second pitch is 1.08 times or more and 1.3 times or less the first pitch.

8. The elastic wave resonator according to claim 5, wherein the gap is 1.04 times or more and 1.08 times or less the first pitch.

9. The elastic wave resonator according to claim 1, wherein the at least one second electrode fingers is formed in the same number at respective ends in the propagation direction of the first electrode finger.

10. The elastic wave resonator according to claim 1, wherein a plurality of second electrode fingers is arranged at a first pitch in a propagation direction of an elastic wave at respective ends in the propagation direction of the first electrode finger.

11. The elastic wave resonator according to claim 1, wherein the plurality of strip electrodes is arranged, in the propagation direction, at a second pitch wider than the first pitch, and has a duty ratio higher than a duty ratio of any of the first electrode finger and the plurality of second electrode fingers.

12. The elastic wave resonator according to claim 1, wherein the duty ratio of the plurality of strip electrodes is 1.04 times or more and 1.43 times or less a duty ratio of any of the first electrode finger and the plurality of second electrode fingers.

13. The elastic wave resonator according to claim 1, wherein
a certain number of the plurality of first electrode fingers and a certain number of the plurality of second electrode fingers extend from a first bus bar on the piezoelectric body, and a remaining number of the plurality of first electrode fingers and a remaining number of the plurality of second electrode fingers extend from a second bus bar on the piezoelectric body facing the first bus bar, and
the certain number of the plurality of first electrode fingers and the certain number of the plurality of second electrode fingers extending from the first bus bar and the remaining number of the plurality of first electrode fingers and the remaining number of the plurality of second electrode fingers extending from the second bus bar are alternately arranged in the propagation direction.

14. The elastic wave resonator according to claim 13, wherein
the IDT electrode comprises a plurality of dummy electrodes extending from each of the first bus bar and the second bus bar, and
the certain number of the plurality of first electrode fingers and the certain number of the plurality of second electrode fingers extending from the first bus bar are opposed to the plurality of dummy electrodes extending from the second bus bar via a void, and the remaining number of the plurality of first electrode fingers and the remaining number of the plurality of second electrode fingers extending from the second bus bar are opposed to the plurality of dummy electrodes extending from the first bus bar via a void.

15. The elastic wave resonator according to claim 3, wherein
the reflective multilayer film comprises a first layer and a second layer that are alternately laminated,
the first layer contains SiO₂ as a main ingredient, and
the second layer contains any of HfO₂, Ta₂O₅, ZrO₂, TiO₂, and MgO as a main ingredient.

16. An elastic wave filter comprising at least one or more of the elastic wave resonators described in claim 1.

17. A demultiplexer comprising:
an antenna terminal;
a transmission filter configured to filter a transmission signal and output the filtered transmission signal to the antenna terminal; and
a reception filter configured to filter a reception signal from the antenna terminal,
wherein at least one of the transmission filter or the reception filter comprises the elastic wave filter described in claim 16.

18. A communication apparatus comprising:
an antenna;
the demultiplexer described in claim 17, the demultiplexer comprising the antenna terminal connected to the antenna; and
an IC connected to the transmission filter and the reception filter.
